(19) United States
(12) Patent Application Publication
(10) Pub. No.: US 2025/0275330 A1
(43) Pub. Date: Aug. 28, 2025

(54) DISPLAY DEVICE

(71) Applicant: Samsung Display Co., LTD., Yongin-si (KR)

(72) Inventors: Gwang Geun LEE, Yongin-si (KR); Ji Wook MOON, Yongin-si (KR); Young Kyo SEO, Yongin-si (KR); Ki Chang EOM, Yongin-si (KR)

(73) Assignee: Samsung Display Co., LTD., Yongin-si (KR)

(21) Appl. No.: 19/009,350

(22) Filed: Jan. 3, 2025

(30) Foreign Application Priority Data
Feb. 23, 2024 (KR) 10-2024-0026531

(51) Int. Cl. H10H 29/32; H01L 25/075; H01L 25/16; H10H 29/49; H10H 29/80; H10K 59/121; H10K 59/131

(52) U.S. Cl. CPC H10H 29/32; H01L 25/0753; H01L 25/167; H10H 29/49; H10H 29/942; H10K 59/1213; H10K 59/131

(57) ABSTRACT

A display device includes a pixel circuit layer including a sub-pixel circuit having at least one transistor, an electrode layer disposed on the pixel circuit layer and including a pixel electrode electrically connected to the sub-pixel circuit and a common electrode spaced apart from the pixel electrode, a light emitting stack structure disposed on the electrode layer and including a first semiconductor layer, a second semiconductor layer disposed on the first semiconductor layer, and an active layer interposed between the first and second semiconductor layers, a first bonding electrode connected to the first semiconductor layer and electrically connected to the pixel electrode, a second bonding electrode connected to a portion of the second semiconductor layer not overlapping the first semiconductor layer and the active layer and electrically connected to the common electrode, and a sub-common electrode covering at least a top surface of the light emitting stack structure.

### CROSS-REFERENCE TO RELATED APPLICATION(S)

The application claims priority to and benefits of Korean patent application No. 10-2024-0026531 under 35 U.S.C. § 119 (a), filed on Feb. 23, 2024, in the Korean Intellectual Property Office (KIPO), the entire contents of which are incorporated herein by reference.

### BACKGROUND

### 1. Technical Field

The disclosure generally relates to a display device and an electronic device including the display device.

### 2. Description of Related Art

A display device may include multiple pixels, and each of the pixels may emit light. The display device may display an image by combining lights emitted from the pixels.

Many studies have been conducted so as to improve the light emission efficiency of each of the pixels included in the display device.

### SUMMARY

Embodiments provide a display device including a pixel having improved light emission efficiency.

In accordance with an embodiment of the disclosure, a display device may include a pixel circuit layer including a sub-pixel circuit having at least one transistor, an electrode layer disposed on the pixel circuit layer and including a pixel electrode electrically connected to the sub-pixel circuit and a common electrode spaced apart from the pixel electrode, a light emitting stack structure disposed on the electrode layer and including a first semiconductor layer, a second semiconductor layer disposed on the first semiconductor layer, and an active layer interposed between the first semiconductor layer and the second semiconductor layer, a first bonding electrode connected to the first semiconductor layer and electrically connected to the pixel electrode, a second bonding electrode connected to a portion of the second semiconductor layer not overlapping the first semiconductor layer and the active layer in a plan view and electrically connected to the common electrode, and a sub-common electrode covering at least a top surface of the light emitting stack structure.

The sub-common electrode may further cover a portion of a side surface of the light emitting stack structure, which is adjacent to the top surface of the light emitting stack structure.

A side surface of the active layer and a side surface of the first semiconductor layer may not be covered by the sub-common electrode.

The display device may further include an insulating film covering at least a portion of an outer circumferential surface of the light emitting stack structure. The insulating film may be interposed between the sub-common electrode and the portion of the side surface of the light emitting stack structure.

The insulating film may be further interposed between the sub-common electrode and the top surface of the light emitting stack structure.

A level of a voltage applied to the sub-common electrode and a level of a voltage applied to the common electrode may be equal.

A level of a voltage applied to the sub-common electrode and a level of a voltage applied to the common electrode may be different.

The level of the voltage applied to the sub-common electrode may be between the level of the voltage applied to the common electrode and a level of a voltage applied to the pixel electrode.

In accordance with an embodiment of the disclosure, a display device may include a pixel circuit layer including a sub-pixel circuit having at least one transistor, an electrode layer disposed on the pixel circuit layer and including a pixel electrode electrically connected to the sub-pixel circuit and a common electrode spaced apart from the pixel electrode, an adhesive layer disposed on the common electrode, a light emitting stack structure disposed on the adhesive layer and including a first semiconductor, a second semiconductor layer disposed under the first semiconductor layer, and an active layer interposed between the first semiconductor layer and the second semiconductor layer, a first bonding electrode connected to the first semiconductor layer and electrically connected to the pixel electrode, a second bonding electrode connected to a portion of the second semiconductor layer not overlapping the first semiconductor layer and the active layer in a plan view and electrically connected to the common electrode, a cover electrode covering a bottom surface of the light emitting stack structure and a portion of a side surface adjacent to the bottom surface of the light emitting stack structure, and a bridge electrode electrically connected to each of the cover electrode and the common electrode.

A side surface of the active layer and a side surface of the first semiconductor layer may not be covered by the cover electrode.

The display device may further include an insulating film covering at least a portion of an outer circumferential surface of the light emitting stack structure. The insulating film may be interposed between the cover electrode and the portion of the side surface of the light emitting stack structure.

The insulating film may be further interposed between the cover electrode and the bottom surface of the light emitting stack structure.

In accordance with an embodiment of the disclosure, a display device may include a pixel circuit layer including a sub-pixel circuit having at least one transistor, an electrode layer disposed on the pixel circuit layer and including a pixel electrode electrically connected to the sub-pixel circuit, a common electrode spaced apart from the pixel electrode, and a sub-common electrode spaced apart from each of the pixel electrode and the common electrode, an adhesive layer disposed on the sub-common electrode, a light emitting stack structure disposed on the adhesive layer and including a first semiconductor, a second semiconductor layer disposed under the first semiconductor layer, and an active layer interposed between the first semiconductor layer and the second semiconductor layer, a first bonding electrode connected to the first semiconductor layer and electrically connected to the pixel electrode, a second bonding electrode connected to a portion of the second semiconductor layer not overlapping the first semiconductor layer and the active layer in a plan view and electrically connected to the common electrode, a cover electrode covering a bottom surface of the light emitting stack structure and a portion of a side surface adjacent to the bottom surface of the light emitting stack structure, and a bridge electrode electrically connected to each of the cover electrode and the common electrode.

A side surface of the active layer and a side surface of the first semiconductor layer may not be covered by the cover electrode.

The display device may further include an insulating film covering at least a portion of an outer circumferential surface of the light emitting stack structure. The insulating film may be interposed between the cover electrode and the portion of the side surface of the light emitting stack structure.

The insulating film may be further interposed between the cover electrode and the bottom surface of the light emitting stack structure.

A level of a voltage applied to the sub-common electrode and a level of a voltage applied to the common electrode may be equal.

A level of a voltage applied to the sub-common electrode and a level of a voltage applied to the common electrode may be different.

The level of the voltage applied to the sub-common electrode may be between the level of the voltage applied to the common electrode and a level of a voltage applied to the pixel electrode.

In accordance with an embodiment of the disclosure, an electronic device may include a processor to provide input image data, and a display device to display an image based on the input image data. The display device may include a pixel circuit layer including a sub-pixel circuit having at least one transistor, an electrode layer disposed on the pixel circuit layer and including a pixel electrode electrically connected to the sub-pixel circuit and a common electrode spaced apart from the pixel electrode, a light emitting stack structure disposed on the electrode layer and including a first semiconductor layer, a second semiconductor layer disposed on the first semiconductor layer, and an active layer interposed between the first semiconductor layer and the second semiconductor layer, a first bonding electrode connected to the first semiconductor layer and electrically connected to the pixel electrode, a second bonding electrode connected to a portion of the second semiconductor layer not overlapping the first semiconductor layer and the active layer in a plan view and electrically connected to the common electrode, and a sub-common electrode covering at least a top surface of the light emitting stack structure.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating a display device in accordance with embodiments of the disclosure.

FIG. 2 is a schematic block diagram illustrating one sub-pixel among sub-pixels included in the display device shown in FIG. 1.

FIG. 3 is a plan view illustrating a display panel constituting the display device shown in FIG. 1.

FIG. 4 is a schematic cross-sectional view illustrating an embodiment of the display panel shown in FIG. 3.

FIG. 5 is a schematic cross-sectional view illustrating another embodiment of the display panel shown in FIG. 3.

FIG. 6 is a plan view illustrating a first embodiment of one pixel among pixels included in the display panel shown in FIG. 3.

FIGS. 7 and 8 are schematic cross-sectional views illustrating the pixel in accordance with the first embodiment shown in FIG. 6.

FIGS. 9 and 10 are schematic cross-sectional views illustrating a modified embodiment of the pixel in accordance with the first embodiment shown in FIG. 6.

FIG. 11 is a plan view illustrating a second embodiment of the one pixel among the pixels included in the display panel shown in FIG. 3.

FIGS. 12 and 13 are schematic cross-sectional views illustrating the pixel in accordance with the second embodiment shown in FIG. 11.

FIGS. 14 and 15 are schematic cross-sectional views illustrating a modified embodiment of the pixel in accordance with the second embodiment shown in FIG. 11.

FIG. 16 is a plan view illustrating a third embodiment of the one pixel among the pixels included in the display panel shown in FIG. 3.

FIGS. 17 and 18 are schematic cross-sectional views illustrating the pixel in accordance with the third embodiment shown in FIG. 16.

FIGS. 19 and 20 are schematic cross-sectional views illustrating a modified embodiment of the pixel in accordance with the third embodiment shown in FIG. 16.

FIG. 21 is a schematic block diagram illustrating a display system in accordance with an embodiment of the disclosure.

FIGS. 22 to 25 are perspective views illustrating applications of the display system shown in FIG. 21.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The technical terms used herein are used only for the purpose of illustrating a specific embodiment and not intended to limit the embodiment. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ). In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

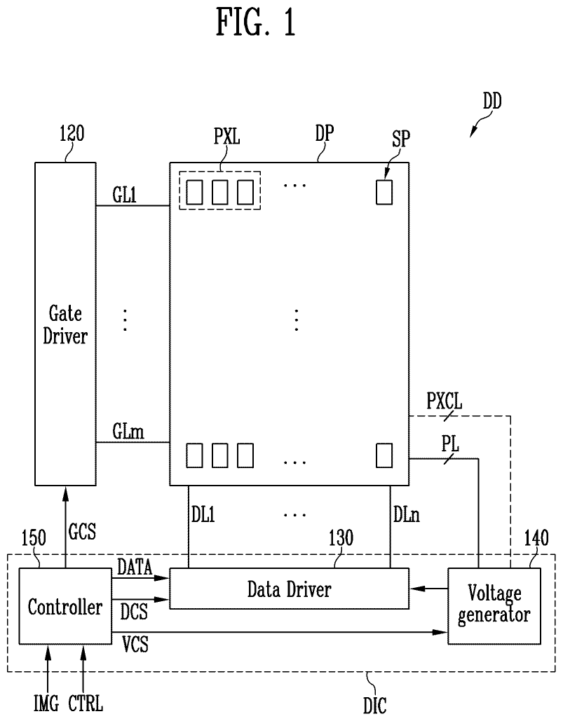

FIG. 1 is a schematic block diagram illustrating a display device in accordance with embodiments of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

The sub-pixels SP may generate lights of a color. For example, each of the sub-pixels SP may generate lights of one of red, green, blue, cyan, magenta, yellow, white, and the like.

Two or more sub-pixels among the sub-pixels SP may constitute a pixel PXL. For example, a pixel PXL may include three sub-pixels as shown in FIG. 1. The pixel PXL may emit lights of various colors with various luminances according to a combination of lights emitted from the sub-pixels included in the pixel PXL.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal, and the like.

The gate driver 120 may be disposed at a side of the display panel DP. However, embodiments are not limited thereto. For example, the gate driver 120 may be divided into two or more drivers which are physically and/or logically divided, and these drivers may be disposed at a side of the display panel DP and another side of the display panel DP, which is opposite to the side. As such, in some embodiments, the gate driver 120 may be disposed in various forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLn. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device DD. The voltage generator 140 may generate multiple voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages to the sub-pixels SP. For example, in a sensing operation for sensing electrical characteristics of transistors and/or light emitting elements of the sub-pixels SP, a reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

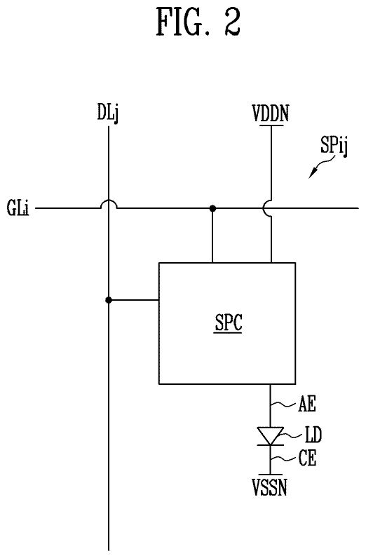

FIG. 2 is a schematic block diagram illustrating one sub-pixel among the sub-pixels included in the display device shown in FIG. 1. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 is schematically illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another one of the power lines PL, to receive a second power voltage. The first power voltage may have a voltage level higher than a voltage level of the second power voltage.

The light emitting element LD may be connected between a pixel electrode AE and a common electrode CE. The pixel electrode AE may be connected to the first power voltage node VDDN through the sub-pixel circuit SPC. For example, the pixel electrode AE may be connected to the first power voltage node VDDN through one or more transistors included in the sub-pixel circuit SPC. The common electrode CE may be connected to the second power voltage node VSSN. In an embodiment, the pixel electrode AE may be an anode electrode, and the common electrode CE may be a cathode electrode. The light emitting element LD may be configured to emit light according to a current flowing from the pixel electrode AE to the common electrode CE.

The sub-pixel circuit SPC may be connected to an ith gate line GLi among the first to mth gate lines GL1 to GLm shown in FIG. 1 and a jth data line DLj among the first to nth data lines DL1 to DLn shown in FIG. 1. In response to a gate signal received through the ith gate line GLi, the sub-pixel circuit SPC may control the light emitting element LD to emit light according to a data signal received through the jth data line DLj. In embodiments, the sub-pixel circuit SPC may be further connected to the pixel control lines PXCL as shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. In embodiments, the transistors of the sub-pixel circuit SPC may include a Metal Oxide Silicon Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, or the like.

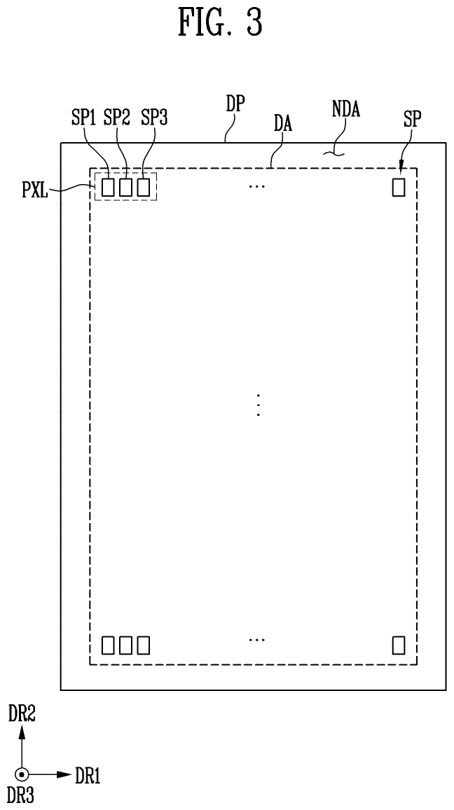

FIG. 3 is a plan view illustrating the display panel constituting the display device shown in FIG. 1.

Referring to FIG. 3, a display panel DP may include a display area DA and a non-display area NDA. The display panel DP may display an image through the display area DA. The non-display area NDA may be disposed at the periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another embodiment, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may constitute one pixel PXL. In FIG. 3, it is illustrated that the pixel PXL includes three sub-pixels SP1, SP2, and SP3. However, embodiments are not limited thereto. For example, the pixel PXL may include two sub-pixels. Hereinafter, for convenience of description, an embodiment that the pixel PXL includes first to third sub-pixels SP1, SP2, and SP3 is described.

Each of the first to third sub-pixels SP1, SP2, and SP3 may generate light of one of various colors such as red, green, blue, cyan, magenta, and yellow. Hereinafter, for clear and simple description, an embodiment that the first sub-pixel SP1 is configured to generate light of a red color, the second sub-pixel SP2 is configured to generate light of a green color, and the third sub-pixel SP3 is configured to generate light of a blue color is described.

Each of the first to third sub-pixels SP1, SP2, and SP3 may include at least one light emitting element configured to generate light. In embodiments, light emitting elements of the first to third sub-pixels SP1, SP2, and SP3 may generate light of a same color. For example, the light emitting elements of the first to third sub-pixels SP1, SP2, and SP3 may generate light of a blue color. In other embodiments, the light emitting elements of the first to third sub-pixels SP1, SP2, and SP3 may generate lights of different colors. For example, the light emitting elements of the first to third sub-pixels SP1, SP2, and SP3 may generate lights a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 150, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into one integrated circuit distinguished from the display panel DP.

The display area DA may have various shapes in a plan view. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include a material having flexibility.

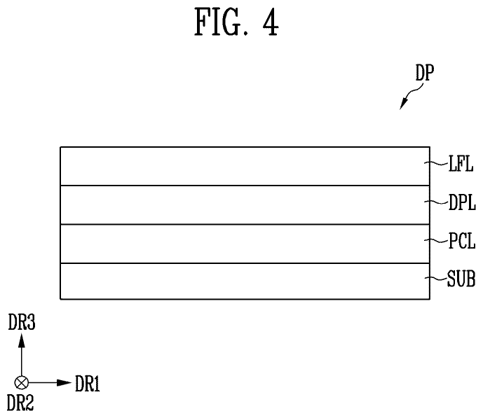

FIG. 4 is a schematic cross-sectional view illustrating an embodiment of the display panel shown in FIG. 3.

Referring to FIG. 4, a display panel DP may include a substrate SUB, and a pixel circuit layer PCL, a display element layer DPL, and a light functional layer LFL, which are sequentially stacked in a third direction DR3 intersecting the first and second directions DR1 and DR2 on the substrate SUB.

The substrate SUB may be made of an insulating material such as glass or a resin. For example, the substrate SUB may be a glass substrate. In another embodiment, the substrate SUB may be a polyimide (PI) substrate. In another embodiment, the substrate SUB may be a silicon wafer substrate formed using a semiconductor process.

In embodiments, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may constitute a sub-pixel circuit SPC of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines for driving the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or light scattering particles. For example, color conversion particles may include quantum dots. The quantum dots may change a wavelength (or color) of light emitted from the display element layer DPL. The light functional layer LFL may further include light scattering patterns having light scattering particles. In embodiments, the light conversion patterns and the light scattering patterns may be omitted.

The light functional layer LFL may further include a color filter layer including color filters. The color filter may selectively transmit light having a specific wavelength (or specific color). In embodiments, the color filter layer may be omitted.

A window (not illustrated) for protecting an exposed surface (or top surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

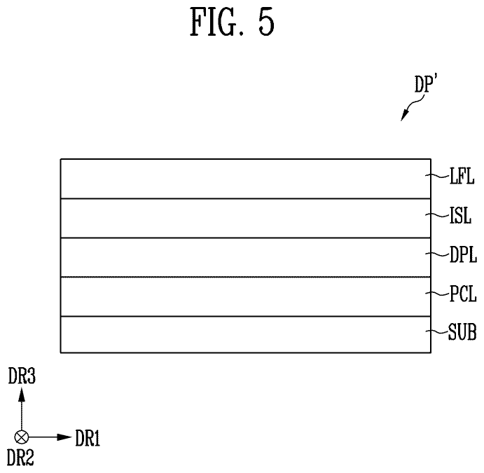

FIG. 5 is a schematic cross-view illustrating another embodiment of the display panel shown in FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured subsequently identical (or similar) to the substrate SUB, the pixel circuit layer PCL, the display element layer DPL, and the light functional layer LFL, which are described with reference to FIG. 4, respectively. Therefore, descriptions of overlapping portions will be omitted.

The input sensing layer ISL may sense a user input from a top surface (or display surface) of the display panel DP′. The input sensing layer ISL may include components suitable for sensing an external object such as a hand of a user or a pen. For example, the input sensing layer ISL may include touch electrodes.

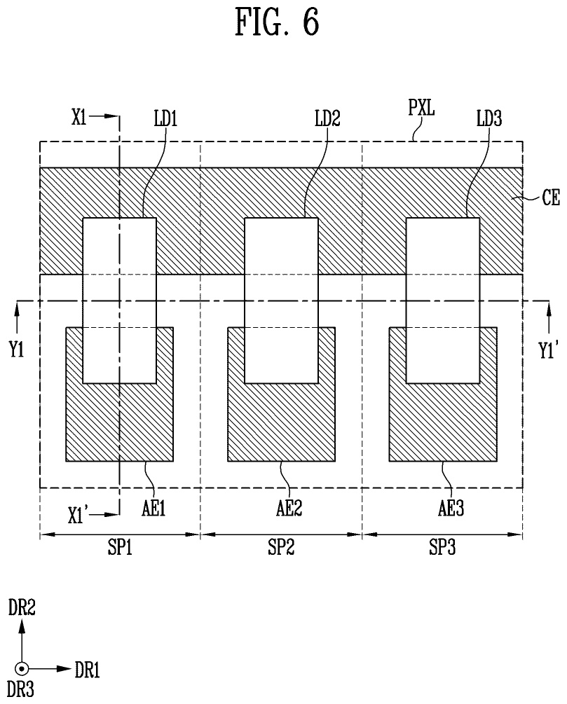

FIG. 6 is a plan view illustrating a first embodiment of one pixel among the pixels included in the display panel shown in FIG. 3.

Referring to FIG. 6, a pixel PXL may include first to third sub-pixels SP1, SP2, and SP3. The first to third sub-pixels SP1, SP2, and SP3 may be arranged in the first direction DR1. However, the arrangement of the first to third sub-pixels SP1, SP2, and SP3 included in the pixel PXL is not limited thereto, and may be variously changed. For example, the first to third sub-pixels SP1, SP2, and SP3 may be arranged in zigzag.

First to third pixel electrodes AE1, AE2, and AE3 may be disposed in the first to third sub-pixels SP1, SP2, and SP3, respectively. The first pixel electrode AE1 may be provided as a pixel electrode (AE shown FIG. 2) connected to a sub-pixel circuit (SPC shown in FIG. 2) of the first sub-pixel SP1. The second pixel electrode AE2 may be provided as a pixel electrode (AE shown in FIG. 2) connected to a sub-pixel circuit (SPC shown in FIG. 2) of the second sub-pixel SP2. The third pixel electrode AE3 may be provided as a pixel electrode (AE shown in FIG. 2) connected to a sub-pixel circuit (SPC shown in FIG. 2) of the third sub-pixel SP3.

A common electrode CE may be spaced apart from the first to third pixel electrodes AE1, AE2, and AE3. The common electrode CE and the first to third pixel electrodes AE1, AE2, and AE3 may be disposed at a same height. The common electrode CE and the first to third pixel electrodes AE1, AE2, and AE3 may define an electrode layer. The common electrode CE and the first to third pixel electrodes AE1, AE2, and AE3 may be implemented as patterns of the electrode layer. The common electrode CE may be spaced apart from the first to third pixel electrodes AE1, AE2, and AE3 in the second direction DR2. In embodiments, the common electrode CE may extend in the first direction DR1 and may be used as a common electrode of the pixel PXL and other pixels adjacent to the pixel PXL. Although not shown in the drawing, the common electrode CE may extend in the second direction DR2 in addition to the first direction DR1 and may be used as a common electrode of all the sub-pixels SP shown in FIG. 3. As such, the common electrode CE may have various shapes.

First to third light emitting elements LD1, LD2, and LD3 may be disposed on the first to third pixel electrodes AE1, AE2, and AE3 and the common electrode CE. The first light emitting element LD1 may be electrically connected to the first pixel electrode AE1 and the common electrode CE. The first light emitting element LD1 may be provided as a light emitting element (LD shown in FIG. 2) connected to the sub-pixel circuit (SPC shown in FIG. 2) of the first sub-pixel SP1. The second light emitting element LD2 may be electrically connected to the second pixel electrode AE2 and the common electrode CE. The second light emitting element LD2 may be provided as a light emitting element (LD shown in FIG. 2) connected to the sub-pixel circuit (SPC shown in FIG. 2) of the second sub-pixel SP2. The third light emitting element LD3 may be electrically connected to the third pixel electrode AE3 and the common electrode CE. The third light emitting element LD3 may be provided as a light emitting element (LD shown in FIG. 2) connected to the sub-pixel circuit (SPC shown in FIG. 2) of the third sub-pixel SP3.

The first light emitting element LD1, the second light emitting element LD2, and the third light emitting element LD3 may be inorganic light emitting diodes including an inorganic light emitting material. However, embodiments are not limited thereto. For example, the first light emitting element LD1, the second light emitting element LD2, and the third light emitting element LD3 may be organic light emitting diodes including an organic light emitting material.

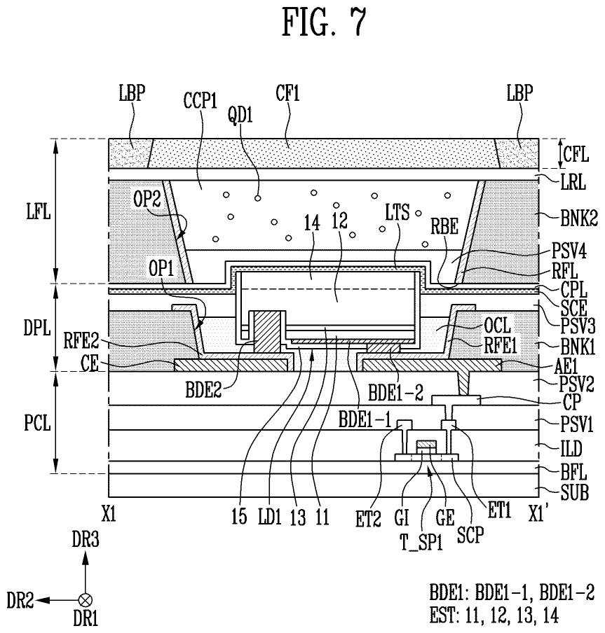

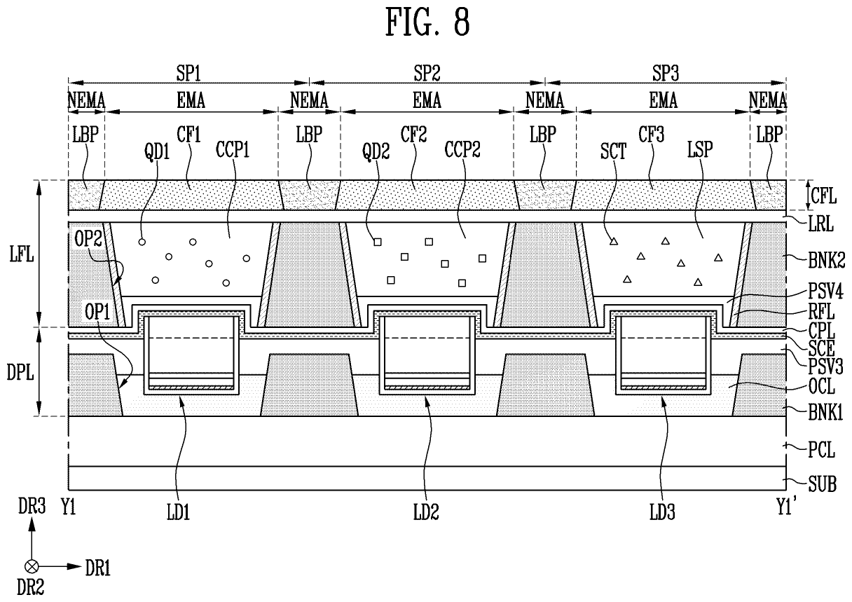

FIGS. 7 and 8 are schematic cross-sectional views illustrating the pixel in accordance with the first embodiment shown in FIG. 6. FIG. 7 is a schematic cross-sectional view taken along line X1-X1′ shown in FIG. 6, and FIG. 8 is a schematic cross-sectional view taken along line Y1-Y1′ shown in FIG. 6.

Referring to FIGS. 6 and 7, a pixel circuit layer PCL, a display element layer DPL, and a light functional layer LFL may be sequentially disposed on a substrate SUB.

The pixel circuit layer PCL may include insulating layers, semiconductor patterns, and conductive patterns, which are stacked on the substrate SUB. The insulating layers may include a buffer layer BFL, one or more interlayer insulating layers ILD, and one or more passivation layers PSV1 and PSV2. The semiconductor patterns and the conductive patterns may be located between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit (SPC shown in FIG. 2) of each of the first to third sub-pixels SP1, SP2, and SP3 may include transistors and one or more capacitors. The semiconductor patterns and the conductive patterns of the pixel circuit layer PCL may serve as the transistors and the capacitors of the sub-pixel circuit SPC. The conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused into circuit elements and lines, which are included in the pixel circuit layer PCL. The buffer layer BFL may include an inorganic insulating layer including an inorganic material. In embodiments, the buffer layer BFL may include at least one of silicon nitride, silicon oxide, silicon oxynitride, and a metal oxide such as aluminum oxide. The buffer layer BFL may be provided as a single layer or a multi-layer. In case that the buffer layer BFL is provided as a multi-layer, layers of the multi-layer may be formed of a same material or be formed of different materials.

In embodiments, although not shown in FIG. 7, one or more barrier layers may be disposed between the substrate SUB and the buffer layer BFL. Each of the barrier layers may include polyimide.

A transistor T_SP1 may be disposed on the buffer layer BFL. The transistor T_SP1 may be one of the transistors of the sub-pixel circuit SPC included in the first sub-pixel SP1. For example, the transistor T_SP1 may be a transistor connected to the first pixel electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be another one of the source electrode and the drain electrode. For example, the first terminal ET1 may be a source electrode, and the second terminal ET2 may be a drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the transistor T_SP1 in the third direction DR3. The channel region may be a semiconductor pattern undoped with an impurity, and may be an intrinsic semiconductor. Each of the first contact region and the second contact region may be a semiconductor pattern doped with an impurity. For example, a p-type impurity may be used as the impurity, but embodiments are not limited thereto.

The semiconductor pattern SCP may include one of various types of semiconductors, e.g., one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride, silicon oxide, silicon oxynitride, and a metal oxide such as aluminum oxide. However, the interlayer insulating layers ILD are not limited thereto. For example, one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL and may cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP in the third direction DR3. The gate electrode GE may be provided as a single layer including at least one of copper (Cu), molybdenum (Mo), tungsten (W), aluminum neodymium (AlNd), titanium (Ti), aluminum (Al), and silver (Ag). In embodiments, the gate electrode GE may be provided as a multi-layer including at least one of molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one of copper (Cu), molybdenum (Mo), tungsten (W), aluminum neodymium (AlNd), titanium (Ti), aluminum (Al), and silver (Ag).

In embodiments, the transistor T_SP1 may be configured as a low temperature poly-silicon transistor. However, embodiments are not limited thereto. In another embodiment, the transistor T_SP1 may be configured as an oxide semiconductor transistor. In embodiments, the sub-pixel circuit of the first sub-pixel SP1 may include different types of transistors. For example, the transistor T_SP1 may be configured as a low temperature poly-silicon transistor, and another transistor of the first sub-pixel SP1 may be configured as an oxide semiconductor transistor. An oxide semiconductor of the corresponding oxide semiconductor transistor may be disposed on one of the interlayer insulating layers ILD instead of an insulating layer on which the semiconductor pattern SCP of the transistor T_SP1 is disposed.

An embodiment that the transistor T_SP1 is a transistor having a top gate structure is described. However, embodiments are not limited thereto. For example, the transistor T_SP1 may be a transistor having a bottom gate structure. The structure of the transistor T_SP1 may be variously changed.

At least a portion of various lines of the display panel DP and/or the display device DD may be further disposed on the interlayer insulating layers ILD.

A first passivation layer PSV1 may be disposed over the interlayer insulating layers ILD and the first and second terminals ET1 and ET2. The passivation layer may be a protective layer or a via layer. The first passivation layer PSV1 may protect components disposed under the first passivation layer PSV1, and provide a flat top surface.

A connection electrode CP may be disposed on the first passivation layer PSV1. The connection electrode CP may be connected to the first terminal ET1 of the transistor T_SP1 while penetrating the first passivation layer PSV1. The connection electrode CP may include at least one of copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed over the connection electrode CP and the first passivation layer PSV1. The second passivation layer PSV2 may protect components disposed under the second passivation layer PSV2, and provide a flat top surface.

Each of the first and second passivation layers PSV1 and PSV2 may be an inorganic insulating layer including an inorganic material and/or an organic insulating layer including an organic material. The inorganic insulating layer may include, for example, at least one of silicon oxide, silicon nitride, silicon oxynitride, and a metal oxide such as aluminum oxide. The organic insulating layer may include, for example, at least one of an acrylic resin, an epoxy resin, a phenolic resin, a polyamide resin, a polyimide resin, an unsaturated polyester resin, a poly-phenylene ether resin, a poly-phenylene sulfide resin, and a benzocyclobutene resin.

The display element layer DPL may be disposed on the second passivation layer PSV2. The display element layer DPL may include a first pixel electrode AE1, a common electrode CE, a first bank BNK1, first and second reflective electrodes RFE1 and RFE2, a first light emitting element LD1, an overcoat layer OCL, a third passivation layer PSV3, a sub-common electrode SCE, and a capping layer CPL.

An electrode layer including the first pixel electrode AE1 and a common electrode CE may be disposed on the pixel circuit layer PCL.

The first pixel electrode AE1 may be electrically connected to the connection electrode CP through a contact hole penetrating the second passivation layer PSV2. As such, the first anode pixel AE1 may be electrically connected to the transistor T_SP1.

The common electrode CE may be spaced apart from the first pixel electrode AE1 in the second direction DR2. The common electrode CE may be electrically connected to the second power voltage node VSSN shown in FIG. 2. Accordingly, the second power voltage applied to the second power voltage node VSSN may be transferred to the common electrode CE.

The first bank BNK1 may be disposed on the first pixel electrode AE1 and the common electrode CE. The first bank BNK1 may have a first opening OP1 exposing portions of the first pixel electrode AE1 and the common electrode CE. The first light emitting element LD1 may be disposed in the first opening OP1 of the first bank BNK1. As such, the first bank BNK1 may be provided as a pixel defining layer defining an area in which the first light emitting element LD1 is located.

The first bank BNK1 may include a light blocking material, to prevent light mixture between adjacent sub-pixels. In embodiments, the first bank BNK1 may include an organic material. For example, the first bank BNK1 may include an organic insulating material such as an acrylic resin, an epoxy resin, a phenolic resin, a polyamide resin, or a polyimide resin.

The first reflective electrode RFE1 may be disposed on the exposed portion of the first pixel electrode AE1 and a side surface of the first bank BNK1 adjacent to the exposed portion of the first pixel electrode AE1. The second reflective electrode RFE2 may be disposed on the exposed portion of the common electrode CE and a side surface of the first bank BNK1 adjacent to the exposed portion of the common electrode CE. The first and second reflective electrodes RFE1 and RFE2 may include a conductive material suitable for reflecting light. Accordingly, the light emission efficiency of the first light emitting element LD1 may be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloys thereof. However, embodiments are not limited thereto.

The first light emitting element LD1 may be electrically connected to the first pixel electrode AE1 through the first reflective electrode RFE1. The first light emitting element LD1 may be electrically connected to the common electrode CE through the second reflective electrode RFE2. The first light emitting element LD1 may be bonded to the first and second reflective electrodes RFE1 and RFE2.

The first light emitting element LD1 may include a light emitting stack structure EST including a first semiconductor layer 11, a second semiconductor layer 12 disposed on the first semiconductor layer 11, and an active layer 13 interposed between the first semiconductor layer 11 and the second semiconductor layer 12. In embodiments, the light emitting stack structure EST may further include an auxiliary layer 14 disposed on the second semiconductor layer 12.

The first light emitting element LD1 may include first and second bonding electrodes BDE1 and BDE2 facing a same direction (e.g., a direction opposite to the third direction DR3). The first bonding electrode BDE1 may be connected to the first semiconductor layer 11. The second bonding electrode BDE2 may be connected to a portion of the second semiconductor layer 12 not overlapping the first semiconductor layer 11 and the active layer 13 in the third direction DR3. For example, the second bonding electrode BDE2 may be connected to a portion of the second semiconductor layer 12 exposed as the first semiconductor layer 11 and the active layer 13 are removed by etching. The first light emitting element LD1 may be a flip chip type light emitting element.

In an embodiment, the first bonding electrode BDE1 may include a (1-1)th bonding electrode BDE1-1 connected to a bottom surface of the first semiconductor layer 11 and a (1-2)th bonding electrode BDE1-2 connected to the (1-1)th bonding electrode BDE1-1. The (1-1)th bonding electrode BDE1-1 may be connected to most areas of the bottom surface of the first semiconductor layer 11 within a range in which the (1-1)th bonding electrode BDE1-1 is insulated from the second bonding electrode BDE2. The (1-1)th bonding electrode BDE1-1 may function to secure a sufficiently large connection area with the first semiconductor layer 11. Accordingly, a current density in the active layer 13 may be entirely maintained at a constant level, and thus the light emission area of the first light emitting element LD1 may be relatively increased. For example, the light emission efficiency of the first light emitting element LD1 may be improved.

The first semiconductor layer 11 may provide holes to the active layer 13. The first semiconductor layer 11 may include at least one p-type semiconductor layer. For example, the first semiconductor layer 11 may include at least one of gallium nitride (GaN), aluminum gallium nitride (AlGaN), indium gallium nitride (InGaN), aluminum nitride (AlN), and indium nitride (InN), and be a p-type semiconductor layer doped with a p-type dopant such as magnesium (Mg), zinc (Zn), calcium (Ca), strontium (Sr) or barium (Ba). However, the material constituting the first semiconductor layer 11 is not limited thereto. Various materials may constitute the first semiconductor layer 11. In an embodiment, the first semiconductor layer 11 may include a gallium nitride (GaN) semiconductor material doped with a p-type dopant.

The second semiconductor layer 12 may provide electrons to the active layer 13. The second semiconductor layer 12 may include at least one n-type semiconductor layer. For example, the second semiconductor layer 12 may include at least one of gallium nitride (GaN), aluminum gallium nitride (AlGaN), indium gallium nitride (InGaN), aluminum nitride (AlN), and indium nitride (InN), and be an n-type semiconductor layer doped with an n-type dopant such as silicon (Si), germanium (Ge) or tin (Sn). However, the material constituting the second semiconductor layer 12 is not limited thereto. Various materials may constitute the second semiconductor layer 12. In an embodiment, the second semiconductor layer 12 may include a gallium nitride (GaN) semiconductor material doped with an n-type dopant. In some embodiments, the second semiconductor layer 12 along with the auxiliary layer 14 may constitute an n-type semiconductor layer.

The active layer 13 may be interposed between the first semiconductor layer 11 and the second semiconductor layer 12, and be an area in which electrons and holes are recombined. As electrons and holes may be recombined in the active layer 13, light may be generated, which has a level changed to a low energy level and has a wavelength corresponding to the low energy level. The active layer 13 may be formed in a single quantum well structure or a multi-quantum well structure. In case that the active layer 13 is formed in a multi-quantum well structure, a unit including a barrier layer, a strain reinforcing layer, and a well layer may be repeatedly stacked each other, to form the active layer 13. However, embodiments of the active layer 13 are not limited thereto.

The auxiliary layer 14 may include a gallium nitride (GaN) semiconductor material which is substantially undoped with an impurity or is doped with an impurity in a relatively low concentration. The auxiliary layer 14 along with the second semiconductor layer 12 may constitute an n-type semiconductor layer.

The first bonding electrode BDE1 may be connected to the first semiconductor layer 11, and the second bonding electrode BDE2 may be connected to the second semiconductor layer 12. The first bonding electrode BDE1 may not be physically in contact with the second semiconductor layer 12 and the active layer 13, and the second bonding electrode BDE2 may not be physically in contact with the first semiconductor layer 11 and the active layer 13. In embodiments, the first and second bonding electrodes BDE1 and BDE2 may include a eutectic metal.

The first light emitting element LD1 may further include an insulating film 15 covering at least a portion of an outer circumferential surface of the light emitting stack structure EST. For example, the insulating film 15 may entirely cover an outer circumferential surface of the light emitting stack structure EST except a top surface (i.e., a top surface of the auxiliary layer 14 shown in FIG. 7 or a top surface of the second semiconductor layer 12 in case that the auxiliary layer 14 is omitted). The insulating film 15 may prevent an electrical short circuit which may occur in case that the active layer 13 is in contact with another conductive material except the first and second semiconductor layers 11 and 12. Also, the insulating film 15 may prevent an electrical short circuit which may occur in case that the second bonding electrode BDE2 is in contact with the first semiconductor layer 11 and the active layer 13. The insulating layer 15 may include a transparent insulating material. As shown in FIG. 7, portions of the first and second bonding electrodes BDE1 and BDE2 may be not covered by the insulating film 15 but may be exposed.

A bottom surface of the first bonding electrode BDE1 may be in contact with the first reflective electrode RFE1. Accordingly, the first bonding electrode BDE1 may be electrically connected to the first pixel electrode AE1 through the first reflective electrode RFE1. A bottom surface of the second bonding electrode BDE2 may be in contact with the second reflective electrode RFE2. Accordingly, the second bonding electrode BDE2 may be electrically connected to the common electrode CE through the second reflective electrode RFE2.

The overcoat layer OCL may be disposed in the first opening OP1 in which the first and second reflective electrodes RFE1 and RFE2 and the first light emitting element LD1 are disposed. The overcoat layer OCL may fix the first light emitting element LD1 bonded to the first and second reflective electrodes RFE1 and RFE2 not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed over the first bank BNK1 and the overcoat layer OCL. The third passivation layer PSV3 may protect components disposed under the third passivation layer PSV3, and provide a flat surface. The third passivation layer PSV3 and one of the first and second passivation layers PSV1 and PSV2 may include a same material, but embodiments are not limited thereto.

In embodiments, the third passivation layer PSV3 may not be disposed on a top surface LTS of the first light emitting element LD1. The first light emitting element LD1 may protrude to the light functional layer LFL. The first light emitting element LD1 may be at least partially located in a second opening OP2 of a second bank BNK2. For example, a height of the top surface LTS of the first light emitting element LD1 from the substrate SUB may be greater than a height of a lowermost end RBE of a reflective layer RFL from the substrate SUB. Accordingly, light emitted from the first light emitting element LD1 may be provided to the light functional layer LFL at a relatively high ratio.

The sub-common electrode SCE may be disposed on the third passivation layer PSV. The sub-common electrode SCE may cover at least a top surface of the light emitting stack structure EST (i.e., the top surface of the auxiliary layer 14 shown in FIG. 7 or the top surface of the second semiconductor layer 12 in case that the auxiliary layer 14 is omitted). In embodiments, the sub-common electrode SCE may entirely cover the first light emitting element LD1 and the third passivation layer PSV3 in a plan view. The sub-common electrode SCE may serve as a common electrode of the pixel PXL and other pixels adjacent to the pixel PXL. For example, the sub-common electrode SCE may serve as a common electrode of all the sub-pixels SP shown in FIG. 3.

The sub-common electrode SCE may include a conductive material having a relatively high light transmittance. For example, the sub-common electrode SCE may include at least one of various transparent conductive materials such as indium tin oxide (ITO), indium zinc oxide (IZO), zinc oxide (ZnO), indium gallium zinc oxide (IGZO), and indium tin zinc oxide (ITZO), a metal material formed with a relatively thin thickness to secure a sufficient light transmittance, or a combination thereof.

The sub-common electrode SCE may supplement a limited connection area of the second bonding electrode BDE2 and the second semiconductor layer 12. In case that the first light emitting element LD1 is the flip chip type light emitting element as shown in FIG. 7, it may be difficult to sufficiently secure the connection area of the second bonding electrode BDE2 electrically connected the common electrode CE and the second semiconductor layer 12. In case that the sub-common electrode SCE does not exist, the current density in the active layer 13 may be concentrated on a specific area (e.g., an area adjacent to the second bonding electrode BDE2 in an area between the first bonding electrode BDE1 and the second bonding electrode BDE2), and accordingly, the light emission efficiency in an area except the specific area may be relatively low. In the disclosure, the sub-common electrode SCE covering at least the top surface of the light emitting stack structure EST may perform a function substantially identical (or similar) to a function of the second bonding electrode BDE2 connected to the second semiconductor layer 12. For example, an electric field may be formed in an area between the sub-common electrode SCE and the first bonding electrode BDE1 in addition to the area between the second bonding electrode BDE2 and the first bonding area BDE1. Accordingly, the current density in the active layer 13 may be entirely maintained at a constant level, and thus the light emission area of the first light emitting element LD1 may become relatively large. For example, the light emission efficiency of the first light emitting element LD1 may be improved.

In an embodiment, the sub-common electrode SCE may cover (e.g., directly cover) the entire top surface of the light emitting stack structure EST, which is not covered by the insulating film 15. For example, the entire top surface of the light emitting stack structure EST may be in direct contact with the sub-common electrode SCE. The electric field may be effectively formed in the area between the sub-common electrode SCE and the first bonding electrode BDE1, and thus the light emission efficiency of the first light emitting element LD1 may be further improved.

In an embodiment, the sub-common electrode SCE may further cover a portion of a side surface of the light emitting stack structure EST, which is adjacent to the top surface of the light emitting stack structure EST. For example, as shown in FIG. 7, the sub-common electrode SCE may cover a side surface of the auxiliary layer 14 and at least a portion of a side surface of the second semiconductor layer 12, which is adjacent to the side surface of the auxiliary layer 14. In another embodiment, unlike as shown in FIG. 7, the sub-common electrode SCE may entirely cover the side surface of the auxiliary layer 14 and the side surface of the second semiconductor layer 12. The electric field may be more effectively formed in the area between the sub-common electrode SCE and the first bonding electrode BDE1, and thus the light emission efficiency of the first light emitting element LD1 may be further improved. In accordance with embodiments, the insulating film 15 may be interposed between the sub-common electrode SCE and the portion of the side surface of the light emitting stack structure EST.

In an embodiment, a side surface of the active layer 13 and a side surface of the first semiconductor layer 11 may not be covered by the sub-common electrode SCE. The current density in the active layer 13 may be entirely maintained at a constant level, and thus the light emission efficiency of the first light emitting element LD1 may be further improved.

In an embodiment, a voltage having a level substantially equal to a level of a voltage applied to the common electrode CE may be applied to the sub-common electrode SCE. In accordance with embodiments, in a partial area of the display area (DA shown in FIG. 3) and/or a partial area of the non-display area (NDA shown in FIG. 3), the sub-common electrode SCE may be electrically connected to (or in contact with) the common electrode CE and/or a power line connected to the second power voltage node (VSSN shown in FIG. 2).

In an embodiment, a voltage having a level different from the level of the voltage applied to the common electrode CE may be applied to the sub-common electrode SCE. For example, a voltage having a level between the level of the voltage applied to the common electrode CE and a level of a voltage applied to the first pixel electrode AE1 may be applied to the sub-common electrode SCE. For example, the voltage generator (140 shown in FIG. 1) may generate a third power voltage having a level between the first power voltage and the second power voltage in addition to the first power voltage and the second power voltage. The generated third power voltage may be provided to the sub-common electrode SCE through a partial voltage line among the power lines PL. However, embodiments are not limited thereto, and the level of the voltage applied to the sub-common electrode SCE may be variously changed within a range in which the above-described electric field can be effectively formed.

In case that the sub-common electrode SCE is in direct contact with the light emitting stack structure EST (e.g., in case that the sub-common electrode SCE is in direct contact with at least a portion of the top surface of the auxiliary layer 14 as shown in FIG. 7), a voltage having a level substantially equal to the level of the voltage applied to the common electrode CE may be applied to the sub-common electrode SCE. As compared with an embodiment that a voltage having a level different from the level of the voltage applied to the common electrode CE is applied to the sub-common electrode SCE, the electric field may be more effectively formed in the area between the sub-common electrode SCE and the first bonding electrode BDE1.

The capping layer CPL may be disposed over the sub-common electrode SCE. The capping layer CPL may protect components disposed under the capping layer CPL, such as the first light emitting element LD1, from external moisture, humidity, and the like. In accordance with embodiments, the capping layer CPL may not contact the top surface of the first light emitting element LD1. In an embodiment, the capping layer CPL may entirely cover the sub-common electrode SCE. The capping layer CPL may include at least one of silicon nitride, silicon oxide, silicon oxynitride, and a metal oxide such as aluminum oxide. However, the material of the capping layer CPL is not limited thereto.

In the above, the pixel circuit layer PCL and the display element layer DPL of the first sub-pixel SP1 have been described. Each of the second and third sub-pixels SP2 and SP3 shown in FIG. 6 may be configured identically to the first sub-pixel SP1 within a range in which it is not differently described herein.

The light functional layer LFL may be disposed on the capping layer CPL. The light functional layer LFL may include the second bank BNK2, the reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1 in the third direction DR3. The second bank BNK2 may have the second opening OP2 overlapping the first opening OP1 in the third direction DR3.

The second bank BNK2 may include a light blocking material, to prevent light mixture between adjacent sub-pixels. In embodiments, the second bank BNK2 may include an organic material. For example, the second bank BNK2 may include an organic insulating material such as an acrylic resin, an epoxy resin, a phenolic resin, a polyamide resin, or a polyimide resin.

The reflective layer RFL may be disposed on side surfaces of the second bank BNK2, which are adjacent to the second opening OP2. The reflective layer RFL may reflect incident light, and accordingly, light emission efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy thereof. However, embodiments are not limited thereto.

On the capping layer CPL, the fourth passivation layer PSV4 may be disposed in the second opening OP2. The fourth passivation layer PSV4 may protect components disposed under the fourth passivation layer PSV4, and provide a flat surface. The fourth passivation layer PSV4 and one of the first to third passivation layers PSV1, PSV2, and PSV3 may include a same material, but embodiments are not limited thereto.

On the fourth passivation layer PSV4, the first light conversion pattern CCP1 may be disposed in the second opening OP2.

The first light conversion pattern CCP1 may include color conversion particles and/or light scattering particles. The color conversion particles may convert incident light into light of another color by changing a wavelength of the incident light. The color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 configured to convert light of the blue color into light of a red color. In another embodiment, in case that the first light emitting element LD1 emits light of the red color, the first light conversion pattern CCP1 may include light scattering particles. As such, the particles included in the first light conversion pattern CCP1 may be variously changed according to the first light emitting element LD1.

The low refractive layer LRL may be disposed on the second bank BNK2, the reflective layer RFL, and the first light conversion pattern CCP1. The low refractive layer LRL may have a refractive index lower than a refractive index of the first light conversion pattern CCP1. The low refractive layer LRL may refract or totally reflect light according to an incident angle of the corresponding light. For example, the low refractive layer LRL may reflect light from the first light conversion pattern CCP1 back to the first light conversion pattern CCP1. Accordingly, the light conversion efficiency of the first light conversion pattern CCP1 may be improved.

The color filter layer CFL may be disposed on the low refractive layer LRL. The color filter layer CFL may include a first color filter CF1 and light blocking patterns LBP. The first color filter CF1 may overlap the first light conversion pattern CCP1 in the third direction DR3. The first color filter CF1 may selectively transmit light in a desired wavelength range. In case that the first sub-pixel SP1 is a red sub-pixel, the first color filter CF1 may include a red color filter. The light blocking patterns LBP may include at least one of various kinds of light blocking materials.

Referring to FIGS. 6 and 8, a pixel circuit layer PCL, a display element layer DPL, and a light functional layer LFL may be provided on a substrate SUB.

The pixel circuit layer PCL and the display element layer DPL may be the same as described with reference to FIG. 7. In the pixel circuit layer PCL, sub-pixel circuits respectively corresponding to the first to third sub-pixels SP1, SP2, and SP3 may be provided. In the display element layer DPL, first to third light emitting elements LD1, LD2, and LD3 respectively corresponding to the first to third sub-pixels SP1, SP2, and SP3 may be provided. The first to third light emitting elements LD1, LD2, and LD3 may overlap first openings OP1 of a first bank BNK1 in the third direction DR3. The first light emitting element LD1 may be connected between a common electrode (CE shown in FIG. 7) and a transistor (T_SP1 shown in FIG. 7) included in a sub-pixel circuit of the first sub-pixel SP1. The second light emitting element LD2 may be connected between the common electrode CE and a transistor included in a sub-pixel circuit of the second sub-pixel SP2. The third light emitting element LD3 may be connected between the common electrode CE and a transistor included in a sub-pixel circuit of the third sub-pixel SP3. Hereinafter, overlapping descriptions will be omitted.

The light functional layer LFL may be provided on the display element layer DPL. The light functional layer LFL may be the same as described with reference to FIG. 7. Hereinafter, overlapping descriptions will be omitted.

A second bank BNK2 may have second openings OP2. It may be understood that emission areas EMA and a non-emission area NEMA of the first to third sub-pixels SP1, SP2, and SP3 may be defined by the second bank BNK2. An area overlapping the second bank BNK2 in the third direction DR3 may correspond to the non-emission area NEMA. Areas overlapping the second openings OP2 of the second bank BNK2 in the third direction DR3 may correspond to the emission areas EMA of the first to third sub-pixels SP1, SP2, and SP3.

On a capping layer CPL, a fourth passivation layer PSV4 may be disposed in the second openings OP2. On the fourth passivation layer PSV4, first and second light conversion patterns CCP1 and CCP2 and a light scattering pattern LSP may be disposed in the second openings OP2.

In embodiments, the first to third light emitting elements LD1, LD2, and LD3 may be configured to emit light of a blue color. The first light conversion pattern CCP1 may include first color conversion particles QD1 configured to convert light of the blue color into light of a red color. The second light conversion pattern CCP2 may include second color conversion particles QD2 configured to convert light of the blue color into light of a green color. The light scattering pattern LSP may include light scattering particles SCT which scatter light of the blue color so as to improve light emission efficiency. Accordingly, the first to third sub-pixels SP1, SP2, and SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

In embodiments, the first to third light emitting elements LD1, LD2, and LD3 may be configured to emit lights of the red color, the green color, and the blue color, respectively. Each of the first and second light conversion patterns CCP1 and CCP2 and the light scattering pattern LSP may include the light scattering particles SCT. As such, the particles included in the first and second light conversion patterns CCP1 and CCP2 and the light scattering pattern LSP may be variously changed according to colors of lights emitted from the first to third light emitting elements LD1, LD2, and LD3.

In embodiments, the first and second light conversion patterns CCP1 and CCP2 and the light scattering pattern LSP may be omitted.

A low refractive layer LRL may be disposed on the second bank BNK2, a reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. In embodiments, the low refractive layer LRL may be omitted in an area corresponding to the third sub-pixel SP3.

A color filter layer CFL may be disposed on the low refractive layer LRL. The color filter layer CFL may include the first to third color filters CF1, CF2, and CF3 and light blocking patterns LBP.

Each of the first to third color filters CF1, CF2, and CF3 may selectively transmit light in a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a refractive index greater than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas (or light output area) EMA and the non-emission area NEMA of the first and second sub-pixels SP1, SP2, and SP3 may be defined by the light blocking patterns LBP. An area overlapping the light blocking patterns LBP in the third direction DR3 may correspond to the non-emission area NEMA. Areas not overlapping the light blocking patterns LBP in the third direction DR3 may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlap with each other in the third direction DR3. In another embodiment, a light blocking pattern between the first and second color filters CF1 and CF2 among the light blocking patterns LBP may be formed as a multi-layer in which the first and second color filters CF1 and CF2 overlap with each other in the third direction DR3, and a light blocking pattern between the second and third color filters CF2 and CF3 among the light blocking patterns LBP may be formed as a multi-layer in which the second and third color filters CF2 and CF3 overlap with each other in the third direction DR3. A light blocking pattern between the first color filter CF1 and a third color filter CF3 of an adjacent pixel may be formed as a multi-layer in which the first and third color filters CF1 and CF3 overlap with each other in the third direction DR3. As such, each of the first to third color filters CF1, CF2, and CF3 may extend to the non-emission area NEMA to form the light blocking patterns LBP.

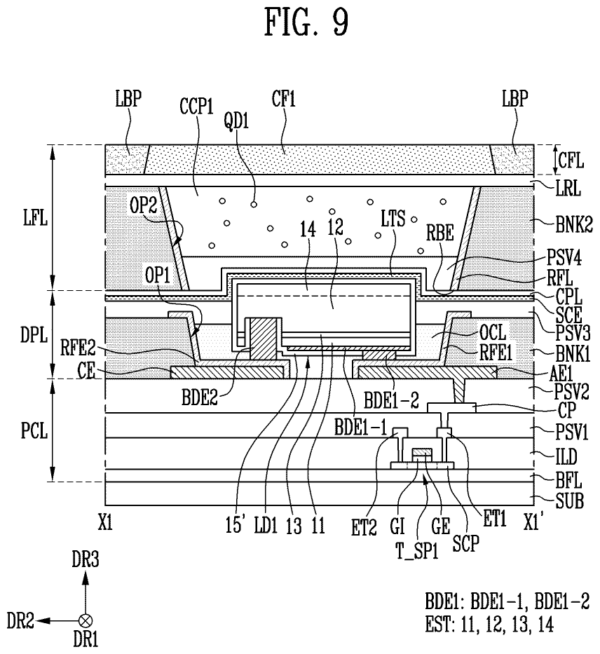

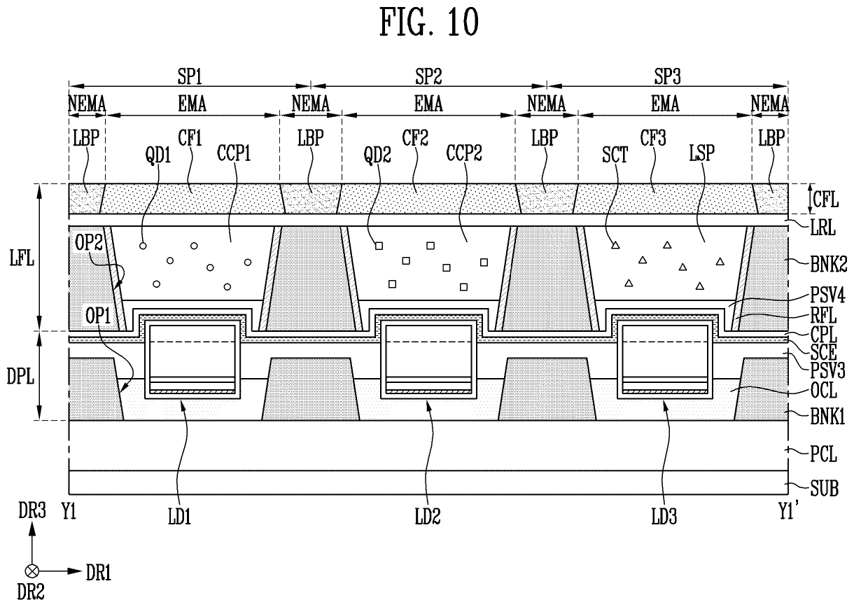

FIGS. 9 and 10 are schematic cross-sectional views illustrating a modified embodiment of the pixel in accordance with the first embodiment shown in FIG. 6. FIG. 9 is a schematic cross-sectional view taken along line X1-X1′ shown in FIG. 6, and FIG. 10 is a schematic cross-sectional view taken along line Y1-Y1′ shown in FIG. 6. Hereinafter, in FIGS. 9 and 10, descriptions of portions overlapping those which have been described with reference to FIGS. 7 and 8, will be omitted.

Referring to FIGS. 6, 9, and 10, a first light emitting element LD1 may further include an insulating film 15′ covering at least a portion of an outer circumferential surface of a light emitting stack structure EST configured with a first semiconductor layer 11, a second semiconductor layer 12, an active layer 13, and an auxiliary layer 14. The insulating film 15′ may entirely cover the outer circumferential surface including a top surface of the light emitting stack structure EST (i.e., a top surface of the auxiliary layer 14 shown in FIG. 9 or a top surface of the second semiconductor layer 12 in case that the auxiliary layer 14 is omitted). For example, unlike the insulating film 15 which has been described with reference to FIG. 7, the insulating film 15′ may further cover the top surface of the light emitting stack structure EST.

Accordingly, the insulating film 15′ may be interposed between a sub-common electrode SCE covering at least the top surface of the light emitting stack structure EST and the light emitting stack structure EST. The sub-common electrode SCE may supplement a limited connection area of a second bonding electrode BDE2 and the second semiconductor layer 12. For example, an electric field may be formed not only in an area between the second bonding electrode BDE2 and a first bonding electrode BDE1 but also in an area between the sub-common electrode SCE and the first bonding electrode BDE1. Accordingly, a current density in the active layer 13 may be entirely maintained at a constant level, and thus the light emission area of the first light emitting element LD1 may be relatively increased. For example, the light emission efficiency of the first light emitting element LD1 may be improved.

In an embodiment, the sub-common electrode SCE may cover the entire top surface of the light emitting stack structure EST, which is covered by the insulating film 15′. The electric field may be effectively formed in the area between the sub-common electrode SCE and the first bonding electrode BDE1, and thus the light emission efficiency of the first light emitting element LD1 may be further improved.

In an embodiment, the sub-common electrode SCE may further cover a portion of a side surface of the light emitting stack structure EST, which is adjacent to the top surface of the light emitting stack structure EST. For example, as shown in FIG. 9, the sub-common electrode SCE may cover a side surface of the auxiliary layer 14 and at least a portion of a side surface of the second semiconductor layer 12, which is adjacent to the side surface of the auxiliary layer 14. In another embodiment, unlike as shown in FIG. 9, the sub-common electrode SCE may entirely cover the side surface of the auxiliary layer 14 and the side surface of the second semiconductor layer 12. The electric field may be more effectively formed in the area between the sub-common electrode SCE and the first bonding electrode BDE1, and thus the light emission efficiency of the first light emitting element LD may be further improved. In accordance with embodiments, the insulating film 15′ may be interposed between the sub-common electrode SCE and the portion of the side surface of the light emitting stack structure EST.

In an embodiment, a side surface of the active layer 13 and a side surface of the first semiconductor layer 11 may not be covered by the sub-common electrode SCE. The current density in the active layer 13 may be entirely maintained at a constant level, and thus the light emission efficiency of the first light emitting element LD1 may be further improved.

In an embodiment, a voltage having a level substantially equal to a level of a voltage applied to a common electrode CE may be applied to the sub-common electrode SCE. In accordance with embodiments, in a partial area of the display area (DA shown in FIG. 3) and/or a partial area of the non-display area (NDA shown in FIG. 3), the sub-common electrode SCE may be electrically connected to (or in contact with) the common electrode CE and/or a power line connected to the second power voltage node (VSSN shown in FIG. 2).

In an embodiment, a voltage having a level different from the level of the voltage applied to the common electrode CE may be applied to the sub-common electrode SCE. For example, a voltage having a level between the level of the voltage applied to the common electrode CE and a level of a voltage applied to a first pixel electrode AE1 may be applied to the sub-common electrode SCE. For example, the voltage generator (140 shown in FIG. 1) may generate a third power voltage having a level between the first power voltage and the second power voltage in addition to the first power voltage and the second power voltage. The generated third power voltage may be provided to the sub-common electrode SCE through a partial voltage line among the power lines PL. However, embodiments are not limited thereto, and the level of the voltage applied to the sub-common electrode SCE may be variously changed within a range in which the above-described electric field can be effectively formed.

In case that the insulating film 15′ is interposed between the sub-common electrode SCE and the top surface of the light emitting stack structure EST (i.e., in case that the sub-common electrode SCE is not in direct contact with the top surface of the light emitting stack structure EST as shown in FIG. 9), a voltage having a level different from the level of the voltage applied to the common electrode CE may be applied to the sub-common electrode SCE. As compared with an embodiment that a voltage having a level substantially equal to the level of the voltage applied to the common electrode CE is applied to the sub-common electrode SCE, the electric field may be more effectively formed in the area between the sub-common electrode SCE and the first bonding electrode BDE1.

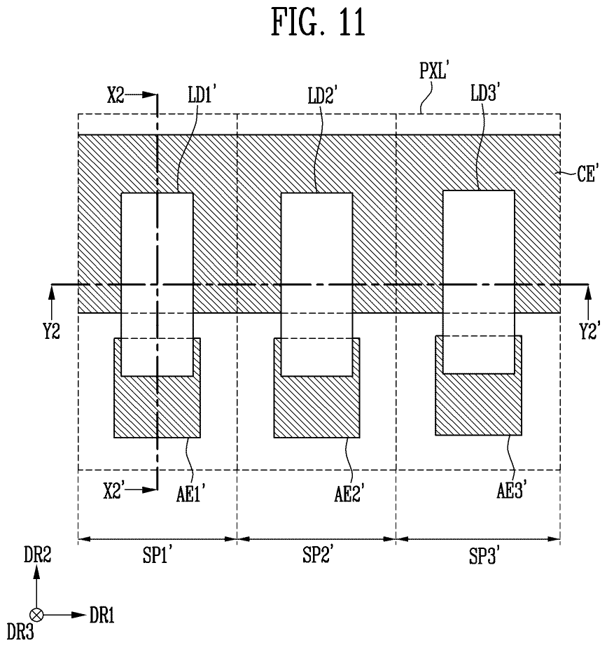

FIG. 11 is a plan view illustrating a second embodiment of the one pixel among the pixels included in the display panel shown in FIG. 3.

Referring to FIG. 11, a pixel PXL′ may include first to third sub-pixels SP1′, SP2′, and SP3′. The first to third sub-pixels SP1′, SP2′, and SP3′ may be arranged in the first direction DR1. However, the arrangement of the pixel PXL′ is not limited thereto, and may be variously changed. For example, the first to third sub-pixels SP1′, SP2′, and SP3′ may be arranged in zigzag.

First to third pixel electrodes AE1′, AE2′, and AE3′ may be disposed in the first to third sub-pixels SP1′, SP2′, and SP3′, respectively. The first pixel electrode AE1′ may be provided as a pixel electrode (AE shown in FIG. 2) of a sub-pixel circuit (SPC shown in FIG. 2) of the first sub-pixel SP1′. The second pixel electrode AE2′ may be provided as a pixel electrode (AE shown in FIG. 2) of a sub-pixel circuit (SPC shown in FIG. 2) of the second sub-pixel SP2′. The third pixel electrode AE3′ may be provided as a pixel electrode (AE shown in FIG. 2) of a sub-pixel circuit (SPC shown in FIG. 2) of the third sub-pixel SP3′.

A common electrode CE′ may be spaced apart from the first to third pixel electrodes AE1′, AE2′, and AE3′. The common electrode CE′ and the first to third pixel electrodes AE1′, AE2′, and AE3′ may be disposed at a same height. The common electrode CE′ and the first to third pixel electrodes AE1′, AE2′, and AE3′ may define an electrode layer. The common electrode CE′ and the first to third pixel electrodes AE1′, AE2′, and AE3′ may be implemented as patterns as the electrode layer. The common electrode CE′ may be spaced apart from the first to third pixel electrodes AE1′, AE2′, and AE3′ in the second direction DR2. In embodiments, the common electrode CE′ may extend in the first direction DR1 and may serve as a common electrode of the pixel PXL′ and other pixels adjacent to the pixel PXL′. Although not shown in the drawing, the common electrode CE′ may extend in the second direction DR2 in addition to the first direction DR1 and may serve as a common electrode of all the sub-pixels SP shown in FIG. 3. As such, the common electrode CE′ may have various shapes.

First to third light emitting elements LD1′, LD2′, and LD3′ may be disposed on the first to third pixel electrodes AE1′, AE2′, and AE3′ and the common electrode CE′. The first light emitting element LD1′ may be electrically connected to the first pixel electrode AE1′ and the common electrode CE′. The first light emitting element LD1′ may be provided as a light emitting element (LD shown in FIG. 2) connected to the sub-pixel circuit (SPC shown in FIG. 2) of the first sub-pixel SP1′. The second light emitting element LD2′ may be electrically connected to the second pixel electrode AE2′ and the common electrode CE′. The second light emitting element LD2′ may be provided as a light emitting element (LD shown in FIG. 2) connected to the sub-pixel circuit (SPC shown in FIG. 2) of the second sub-pixel SP2′. The third light emitting element LD3′ may be electrically connected to the third pixel electrode AE3′ and the common electrode CE′. The third light emitting element LD3′ may be provided as a light emitting element (LD shown in FIG. 2) connected to the sub-pixel circuit (SPC shown in FIG. 2) of the third sub-pixel SP3′.

The first light emitting element LD1′, the second light emitting element LD2′, and the third light emitting element LD3′ may be inorganic light emitting diodes including an inorganic light emitting material. However, embodiments are not limited thereto. In another embodiment, the first light emitting element LD1′, the second light emitting element LD2′, and the third light emitting element LD3′ may be organic light emitting diodes including an organic light emitting material.

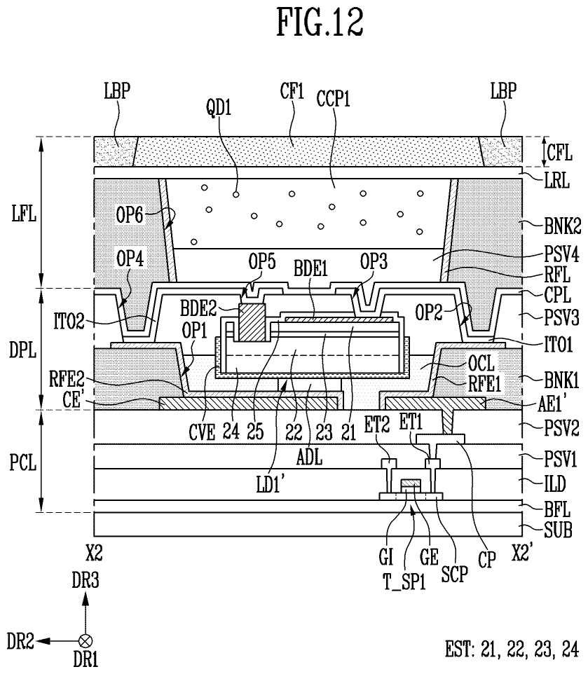

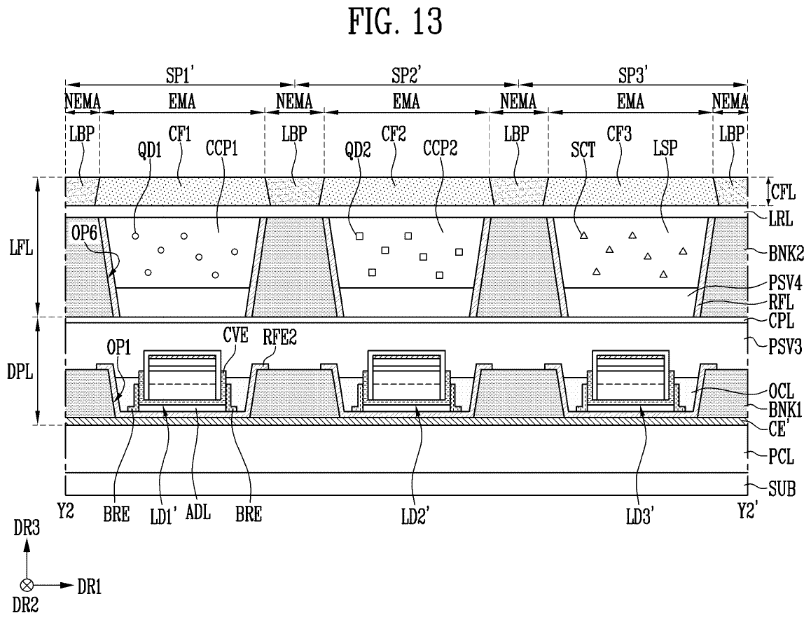

FIGS. 12 and 13 are schematic cross-sectional views illustrating the pixel in accordance with the second embodiment shown in FIG. 11. FIG. 12 is a schematic cross-sectional view taken along line X2-X2′ shown in FIG. 11, and FIG. 13 is a schematic cross-sectional view taken along line Y2-Y2′ shown in FIG. 11.

Referring to FIGS. 11 and 12, a pixel circuit layer PCL, a display element layer DPL, and a light functional layer LFL may be sequentially disposed on a substrate SUB.

The pixel circuit layer PCL may be substantially identical to the pixel circuit layer PCL which has been described with reference to FIGS. 7 and 8. Therefore, descriptions of overlapping portions will be omitted.

The display element layer DPL may be disposed on a second passivation layer PSV2. The display element layer DPL may include a first pixel electrode AE1′, a common electrode CE′, a first bank BNK1, first and second reflective electrodes RFE1 and RFE2, an adhesive layer ADL, an overcoat layer OCL, a first light emitting element LD1′, a third passivation layer PSV3, first and second transparent electrodes ITO1 and ITO2, and a capping layer CPL.

An electrode layer including the first pixel electrode AE1′ and the common electrode CE′ may be disposed on the pixel circuit layer PCL.

The first pixel electrode AE1′ may be electrically connected to a connection electrode CP through a contact hole penetrating the second passivation layer PSV2. As such, the first pixel electrode AE1′ may be electrically connected to a transistor T_SP1.

The common electrode CE′ may be spaced apart from the first pixel electrode AE1′ in the second direction DR2. The common electrode CE′ may be electrically connected to the second power voltage node VSSN shown in FIG. 2. Accordingly, the second power voltage applied to the second power voltage node VSSN may be transferred to the common electrode CE′.

The first bank BNK1 may be disposed on the first pixel electrode AE1′ and the common electrode CE′. The first bank BNK1 may have a first opening OP1 exposing portions of the first pixel electrode AE1′ and the common electrode CE′ in a plan view. The first light emitting element LD1′ may be disposed in the first opening OP1 of the first bank BNK1. As such, the first bank BNK1 may be provided as a pixel defining layer defining an area in which the first light emitting element LD1′ is located.

The first bank BNK1 may include a light blocking material, and prevent light mixture between adjacent sub-pixels. In embodiments, the first bank BNK1 may include an organic material. For example, the first bank BNK1 may include an organic insulating material such as an acrylic resin, an epoxy resin, a phenolic resin, a polyamide resin, or a polyimide resin.

The first reflective electrode RFE1 may be disposed on the exposed portion of the first pixel electrode AE1′ and a side surface of the first bank BNK1 adjacent to the exposed portion of the first pixel electrode AE1′. The second reflective electrode RFE2 may be disposed on the exposed portion of the common electrode CE′ and a side surface of the first bank BNK1 adjacent to the exposed portion of the common electrode CE′. The first and second reflective electrodes RFE1 and RFE2 may include a conductive material suitable for reflecting light. Accordingly, the light emission efficiency of the first light emitting element LD1′ may be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloys thereof. However, embodiments are not limited thereto.

The adhesive layer ADL may be disposed on the common electrode CE′ in the first opening OP1 of the first bank BNK1. In accordance with embodiments, the second reflective electrode RFE2 may be interposed between the common electrode CE′ and the adhesive layer ADL. The adhesive layer ADL may include an insulating material having adhesive properties. For example, the adhesive layer ADL may include an organic insulating material having adhesion. The adhesive layer ADL may have a constant height in the third direction DR3. Accordingly, the first light emitting element LD1′ adhered on the adhesive layer ADL may be spaced apart from components disposed under the adhesive layer ADL. For example, the first light emitting element LD1′ may be spaced apart from the first and second reflective electrodes RFE1 and RFE2 disposed under the adhesive layer ADL. Accordingly, the adhesive layer ADL may prevent an electrical short circuit which may occur in case that a cover electrode CVE included in the first light emitting element LD1′ and the first and second reflective electrodes RFE1 and RFE2 are in contact with each other. Also, the adhesive layer ADL may function to fix the first light emitting element LD1′ attached to the adhesive layer ADL.

On the first and second reflective electrodes RFE1 and RFE2 and the second passivation layer PSV2, the overcoat layer OCL may be disposed in the first opening OP1 of the first bank BNK1. The first light emitting element LD1′ attached on the adhesive layer ADL may be disposed on the overcoat layer OCL. The first light emitting element LD1′ may be partially buried in the overcoat layer OCL.

The overcoat layer OCL along with the above-described adhesive layer ADL may fix the first light emitting element LD1′ not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The first light emitting element LD1′ may include a light emitting stack structure EST including a first semiconductor layer 21, a second semiconductor layer 22 disposed on the first semiconductor layer 21, and an active layer 23 interposed between the first semiconductor layer 21 and the second semiconductor layer 22. In embodiments, the light emitting stack structure EST may further include an auxiliary layer 24 disposed under the second semiconductor layer 22.

The first light emitting element LD1′ may include first and second bonding electrodes BDE1 and BDE2. The first bonding electrode BDE1 may be connected to the first semiconductor layer 21 and disposed on the first semiconductor layer 21. The second bonding electrode BDE2 may be connected to a portion of the second semiconductor layer 22 not overlapping the first semiconductor layer 21 and the active layer 23 in the third direction DR3. For example, the second bonding electrode BDE2 may be connected to a portion of the second semiconductor layer 22 exposed as the first semiconductor layer 21 and the active layer 23 are removed by etching. The second bonding electrode BDE2 may face the third direction DR3. The first light emitting element LD1′ may be a lateral chip type light emitting element.

In an embodiment, the first bonding electrode BDE1 may be connected to most areas of a top surface of the first semiconductor layer 21 within a range in which the first bonding electrode BDE1 is insulated from the second bonding electrode BDE2. For example, the first bonding electrode BDE1 may secure a sufficiently large connection area with the first semiconductor layer 21. Accordingly, a current density in the active layer 23 may be entirely maintained at a constant level, and thus the light emission area of the first light emitting element LD1′ may be relatively increased. For example, the light emission efficiency of the first light emitting element LD1′ may be improved.

The first semiconductor layer 21 may provide holes to the active layer 23. The first semiconductor layer 21 may include at least one p-type semiconductor layer. For example, the first semiconductor layer 21 may include at least one of gallium nitride (GaN), aluminum gallium nitride (AlGaN), indium gallium nitride (InGaN), aluminum nitride (AlN), and indium nitride (InN), and be a p-type semiconductor layer doped with a p-type dopant such as magnesium (Mg), zinc (Zn), calcium (Ca), strontium (Sr) or barium (Ba). However, the material constituting the first semiconductor layer 21 is not limited thereto. Various materials may constitute the first semiconductor layer 21. In an embodiment, the first semiconductor layer 21 may include a gallium nitride (GaN) semiconductor material doped with a p-type dopant.

The second semiconductor layer 22 may provide electrons to the active layer 23. The second semiconductor layer 22 may include at least one n-type semiconductor layer. For example, the second semiconductor layer 23 may include at least one of gallium nitride (GaN), aluminum gallium nitride (AlGaN), indium gallium nitride (InGaN), aluminum nitride (AlN), and indium nitride (InN), and be an n-type semiconductor layer doped with an n-type dopant such as silicon (Si), germanium (Ge) or tin (Sn). However, the material constituting the second semiconductor layer 22 is not limited thereto. Various materials may constitute the second semiconductor layer 22. In an embodiment, the second semiconductor layer 22 may include a gallium nitride (GaN) semiconductor material doped with an n-type dopant. In some embodiments, the second semiconductor layer 22 along with the auxiliary layer 24 may constitute an n-type semiconductor layer.

The active layer 23 may be interposed between the first semiconductor layer 21 and the second semiconductor layer 22, and be an area in which electrons and holes are recombined. As electrons and holes are recombined in the active layer 23, light may be generated, which has a level changed to a low energy level and has a wavelength corresponding to the low energy level. The active layer 23 may be formed in a single quantum well structure or a multi-quantum well structure. In case that the active layer 23 is formed in a multi-quantum well structure, a unit including a barrier layer, a strain reinforcing layer, and a well layer may be repeatedly stacked each other, to form the active layer 23. However, embodiments of the active layer 23 are not limited thereto.

The auxiliary layer 24 may include a gallium nitride (GaN) semiconductor material which is substantially undoped with an impurity or is doped with an impurity in a relatively low concentration. The auxiliary layer 24 along with the second semiconductor layer 22 may constitute an n-type semiconductor layer.

The first bonding electrode BDE1 may be connected to the first semiconductor layer 21, and the second bonding electrode BDE2 may be connected to the second semiconductor layer 22. The first bonding electrode BDE1 may not be physically in contact with the second semiconductor layer 22 and the active layer 23, and the second bonding electrode BDE2 may not be physically in contact with the first semiconductor layer 21 and the active layer 23.

The first light emitting element LD1′ may further include an insulating film 25 covering at least a portion of an outer circumferential surface of the light emitting stack structure EST. For example, the insulating film 25 may entirely cover a portion of the outer circumferential surface except a bottom surface of the light emitting stack structure EST (i.e., a bottom surface of the auxiliary layer 24 shown in FIG. 12 or a bottom surface of the second semiconductor layer 22 in case that the auxiliary layer 24 is omitted). The insulating film 25 may prevent an electrical short circuit which may occur in case that the active layer 23 is in contact with another conductive material except the first and second semiconductor layers 21 and 22. Also, the insulating film 25 may prevent an electrical short circuit which may occur in case that the second bonding electrode BDE2 is in contact with the first semiconductor layer 21 and the active layer 23. The insulating layer 25 may include a transparent insulating material. As shown in FIG. 12, portions of the first and second bonding electrodes BDE1 and BDE2 may be not covered by the insulating film 25 but may be exposed.

The third passivation layer PSV3 may be disposed over the first and second reflective electrodes RFE1 and RFE2, the first light emitting element LD1′, and the overcoat layer OCL. The third passivation layer PSV3 may protect components disposed under the third passivation layer PSV3, and provide a flat surface. The third passivation layer PSV3 and one of a first passivation layer PSV1 and the second passivation layer PSV2 may include a same material, but embodiments are not limited thereto.

The third passivation layer PSV3 may have second to fifth openings OP2, OP3, OP4, and OP5. The second opening OP2 may expose a portion of the first reflective electrode RFE1 in a plan view. The third opening OP3 may expose a top surface of the first bonding electrode BDE1 in a plan view. The fourth opening OP4 may expose a portion of the second reflective electrode RFE2 in a plan view. The fifth opening OP5 may expose a top surface of the second bonding electrode BDE2 in a plan view.

The first and second transparent electrodes ITO1 and ITO2 may be disposed on the third passivation layer PSV3. The first transparent electrode ITO1 may electrically connect the first reflective electrode RFE1 exposed by the second opening OP2 to the first bonding electrode BDE1 exposed by the third opening OP3. The second transparent electrode ITO2 may electrically connect the second reflective electrode RFE2 exposed by the fourth opening OP4 to the second bonding electrode BDE2 exposed by the fifth opening OP5. Accordingly, the first bonding electrode BDE1 may be electrically connected to the first pixel electrode AE1′ through the first transparent electrode ITO1 and the first reflective electrode RFE1. The second bonding electrode BDE2 may be electrically connected to the common electrode CE′ through the second transparent electrode ITO2 and the second reflective electrode RFE2.

In embodiments, the first and second transparent electrodes ITO1 and ITO2 may be formed substantially transparent or translucent to satisfy a light transmittance. In embodiments, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

The capping layer CPL may be disposed on the third passivation layer PSV3. The capping layer CPL may protect components disposed under the capping layer CPL, such as the first and second transparent electrodes ITO1 and ITO2 and the first light emitting element LD1′, from external moisture, humidity, and the like. The capping layer CPL may include at least one of silicon nitride, silicon oxide, silicon oxynitride, and a metal oxide such as aluminum oxide. However, the material of the capping layer CPL is not limited thereto.

In the pixel in accordance with the second embodiment of the disclosure, the first light emitting element LD1′ may further include the cover electrode CVE covering the bottom surface of the light emitting stack structure EST (i.e., the bottom surface of the auxiliary layer 24 shown in FIG. 12 or the bottom surface of the second semiconductor layer 22 in case that the auxiliary layer 24 is omitted) and at least a portion of a side surface adjacent to the bottom surface of the light emitting stack structure EST. In accordance with embodiments, the insulating film 25 may be interposed between the cover electrode CVE and the portion of the side surface of the light emitting stack structure EST. The cover electrode CVE and one of the first and second transparent electrodes ITO1 and ITO2, the first and second reflective electrodes RFE1 and RFE2, the first pixel electrode AE1′, and the common electrode CE′ may include a same material, but embodiments are not limited thereto.

The cover electrode CVE may be electrically connected to the common electrode CE′ through a bridge electrode (BRE shown in FIG. 13) which will be described below with reference to FIG. 13. Therefore, a voltage applied to the common electrode CE′ may be applied to the cover electrode CVE. The cover electrode CVE may supplement a limited connection area of the second bonding electrode BDE2 and the second semiconductor layer 22. In case that the first light emitting element LD1′ is the lateral chip type light emitting element as shown in FIG. 12, it may be difficult to sufficiently secure the connection area of the second bonding electrode BDE2 electrically connected to the common electrode CE′ and the second semiconductor layer 22. In case that that the cover electrode CVE does not exist, the current density in the active layer 23 may be concentrated on a specific area (e.g., an area adjacent to the second bonding electrode BDE2 in an area between the first bonding electrode BDE1 and the second bonding electrode BDE2), and accordingly, the light emission efficiency in an area except the specific area may be relatively low. In the disclosure, the cover electrode CVE covering the bottom surface of the light emitting stack structure EST and the portion of the side surface adjacent to the bottom surface of the light emitting structure EST may perform a function substantially identical (or similar) to a function of the second bonding electrode BDE2 connected to the second semiconductor layer 22. For example, an electric field may be formed in an area between the cover electrode CVE and the first bonding electrode BDE1 in addition to the area between the second bonding electrode BDE2 and the first bonding area BDE1. Accordingly, the current density in the active layer 23 may be entirely maintained at a constant level, and thus the light emission area of the first light emitting element LD1′ may become relatively large. For example, the light emission efficiency of the first light emitting element LD1′ may be improved.

In an embodiment, the cover electrode CVE may cover (e.g., directly cover) the entire bottom surface of the light emitting stack structure EST, which is not covered by the insulating film 25. For example, the entire bottom surface of the light emitting stack structure EST may be in direct contact with the cover electrode CVE. The electric field may be effectively formed in the area between the cover electrode CVE and the first bonding electrode BDE1, and thus the light emission efficiency of the first light emitting element LD1′ may be further improved.

In an embodiment, a side surface of the active layer 23 and a side surface of the first semiconductor layer 21 may not be covered by the cover electrode CVE. The current density in the active layer 23 may be entirely maintained at a constant level, and thus the light emission efficiency of the first light emitting element LD1′ may be further improved.

In an embodiment, the cover electrode CVE may entirely cover a side surface of the auxiliary layer 24 and a side surface of the second semiconductor layer 22. The electric field may be further formed in the area between the cover electrode CVE and the first bonding electrode BDE1, and thus the light emission efficiency of the first light emitting element LD1′ may be further improved. In accordance with embodiments, the insulating film 25 may be interposed between the cover electrode CVE, and the side surface of the auxiliary layer 24 and the side surface of the second semiconductor layer 22.

In the above, the pixel circuit layer PCL and the display element layer DPL of the first sub-pixel SP1′ have been described. Each of the second and third sub-pixels SP2′ and SP3′ shown in FIG. 11 may be configured identically to the first sub-pixel SP1′ within a range in which it is not differently described herein.

A second bank BNK2 may be disposed on the capping layer CPL. The second bank BNK2 may overlap the first bank BNK1 in the third direction DR3. The second bank BNK2 may have a sixth opening OP6 overlapping the first opening OP1 in the third direction DR3.

The second bank BNK2 may include a light blocking material, to prevent light mixture between adjacent sub-pixels. In embodiments, the second bank BNK2 may include an organic material. For example, the second bank BNK2 may include an organic insulating material such as an acrylic resin, an epoxy resin, a phenolic resin, a polyamide resin, or a polyimide resin.

A reflective layer RFL may be disposed on side surfaces of the second bank BNK2, which are adjacent to the sixth opening OP6. The reflective layer RFL may reflect incident light, and accordingly, light emission efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy thereof. However, embodiments are not limited thereto.

On the capping layer CPL, a fourth passivation layer PSV4 may be disposed in the sixth opening OP6. The fourth passivation layer PSV4 may protect components disposed under the fourth passivation layer PSV4, and provide a flat surface. The fourth passivation layer PSV4 and one of the first to third passivation layers PSV1, PSV2, and PSV3 may include a same material, but embodiments are not limited thereto.

On the fourth passivation layer PSV4, a first light conversion pattern CCP1 may be disposed in the sixth opening OP6.

The first light conversion pattern CCP1 may include color conversion particles and/or light scattering particles. The color conversion particles may convert incident light into light of another color by changing a wavelength of the incident light. The color conversion particles may scatter incident light. In embodiments, the color conversion particles may be quantum dots. The light scattering particles may scatter incident light.

The first sub-pixel SP1′ may be a red sub-pixel. In case that the first light emitting element LD1′ emits light of a blue color, the first light conversion pattern CCP1 may include first color conversion particles QD1 configured to convert light of the blue color into light of a red color. In case that the first light emitting element LD1′ emits light of the red color, the first light conversion pattern CCP1 may include light scattering particles. As such, the particles included in the first light conversion pattern CCP1 may be variously changed according to the first light emitting element LD1′.

A low refractive layer LRL may be disposed on the second bank BNK2, the reflective layer RFL, and the first light conversion pattern CCP1. The low refractive layer LRL may have a refractive index lower than a refractive index of the first light conversion pattern CCP1. The low refractive layer LRL may refract or totally reflect light according to an incident angle of the corresponding light. For example, the low refractive layer LRL may reflect light from the first light conversion pattern CCP1 back to the first light conversion pattern CCP1. Accordingly, the light conversion efficiency of the first light conversion pattern CCP1 may be improved.

The color filter layer CFL may be disposed on the low refractive layer LRL. The color filter layer CFL may include a first color filter CF1 and light blocking patterns LBP. The first color filter CF1 may overlap the first light conversion pattern CCP1 in the third direction DR3. The first color filter CF1 may selectively transmit light in a desired wavelength range. In case that the first sub-pixel SP1′ is a red sub-pixel, the first color filter CF1 may include a red color filter. The light blocking patterns LBP may include at least one of various kinds of light blocking materials.

Referring to FIGS. 11 and 13, the pixel circuit layer PCL and the display element layer DPL may be the same as described with reference to FIG. 12. In the pixel circuit layer PCL, sub-pixel circuits respectively corresponding to the first to third sub-pixels SP1′, SP2′, and SP3′ may be provided. In the display element layer DPL, first to third light emitting elements LD1′, LD2′, and LD3′ respectively corresponding to the first to third sub-pixels SP1′, SP2′, and SP3′ may be provided. The first to third light emitting elements LD1′, LD2′, and LD3′ may overlap first openings OP1 of the first bank BNK1 in the third direction DR3. The first light emitting element LD1′ may be connected between the common electrode CE′ and the transistor (T_SP1 shown in FIG. 12) included in a sub-pixel circuit of the first sub-pixel SP1′. The second light emitting element LD2′ may be connected between the common electrode CE′ and a transistor included in a sub-pixel circuit of the second sub-pixel SP2′. The third light emitting element LD3′ may be connected between the common electrode CE′ and a transistor included in a sub-pixel circuit of the third sub-pixel SP3′.

As shown in FIG. 13, the cover electrode CVE may be electrically connected to the common electrode CE′ through a bridge electrode BRE. For example, the bridge electrode BRE may be electrically in contact with the second reflective electrode RFE2 electrically in contact with the common electrode CE′ while being electrically in contact with the cover electrode CVE covering the side surface of the light emitting stack structure EST. In embodiments, the bridge electrode BRE may extend along a side surface of the adhesive layer ADL attached to the cover electrode CVE under the cover electrode CVE. For example, in a structure in a cross-sectional view shown in FIG. 13, a width of the adhesive layer ADL in the first direction DR1 may be substantially equal to or greater than a width of the cover electrode CVE in the first direction DR1, and the bridge electrode BDE may cover (e.g., directly cover) the side surface of the adhesive layer ADL. The adhesive layer ADL may improve the reliability of the bridge electrode BDE. For example, in case that the adhesive layer ADL does not exist, the bridge electrode BRE may not be sufficiently supported in a separation area between the cover electrode CVE and the second reflective electrode RFE2, and accordingly, a problem may occur, in that the bridge electrode BRE may be disconnected. Hereinafter, in relation to the pixel circuit layer PCL and the display element layer DPL, descriptions of portion overlapping those described with reference to FIG. 12 will be omitted.

The light functional layer LFL may be provided on the display element layer DPL. The light functional layer LFL may be the same as described with reference to FIG. 12. Hereinafter, overlapping descriptions will be omitted.

The second bank BNK2 may have sixth openings OP6. It may be understood that emission areas EMA and a non-emission area NEMA of the first to third sub-pixels SP1′, SP2′, and SP3′ may be defined by the second bank BNK2. An area overlapping the second bank BNK2 in the third direction DR3 may correspond to the non-emission area NEMA. Areas overlapping the sixth openings OP6 of the second bank BNK2 in the third direction DR3 may correspond to the emission areas EMA of the first to third sub-pixels SP1′, SP2′, and SP3′.

On a capping layer CPL, a fourth passivation layer PSV4 may be disposed in the sixth openings OP6. On the fourth passivation layer PSV4, the first conversion pattern CCP1, a light conversion pattern CCP2 and a light scattering pattern LSP may be disposed in the sixth openings OP6.

In embodiments, the first to third light emitting elements LD1′, LD2′, and LD3′ may be configured to emit light of a blue color. The first light conversion pattern CCP1 may include the first color conversion particles QD1 configured to convert light of the blue color into light of a red color. The second light conversion pattern CCP2 may include second color conversion particles QD2 configured to convert light of the blue color into light of a green color. The light scattering pattern LSP may include light scattering particles SCT which scatter light of the blue color so as to improve light emission efficiency. Accordingly, the first to third sub-pixels SP1′, SP2′, and SP3′ may be provided as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

In embodiments, the first and second light conversion patterns CCP1 and CCP2 and the light scattering pattern LSP may be configured to emit lights of the red color, the green color, and the blue color, respectively. Each of the first and second light conversion patterns CCP1 and CCP2 and the light scattering pattern LSP may include the light scattering particles SCT. As such, the particles included in the first and second light conversion patterns CCP1 and CCP2 and the light scattering pattern LSP may be variously changed according to colors of lights emitted from the first to third light emitting elements LD1′, LD2′, and LD3′.

In embodiments, the first and second light conversion patterns CCP1 and CCP2 and the light scattering pattern LSP may be omitted.

The low refractive layer LRL may be disposed on the second bank BNK2, a reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. In embodiments, the low refractive layer LRL may be omitted in an area corresponding to the third sub-pixel SP3′.

The color filter layer CFL may be disposed on the low refractive layer LRL. The color filter layer CFL may include the first color filter CF1, a second color filter CF2, a third color filter CF3, and light blocking patterns LBP.

Each of the first to third color filters CF1, CF2, and CF3 may selectively transmit light in a desired wavelength range. In case that the first sub-pixel SP1′ is a red sub-pixel, the first color filter CF1 may include a red color filter. In case that the second sub-pixel SP2′ is a green sub-pixel, the second color filter CF2 may include a green color filter. In case that the third sub-pixel SP3′ is a blue sub-pixel, the third color filter CF3 may include a blue color filter. The first to third color filters CF1, CF2, and CF3 may have a refractive index greater than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas (or light output areas) EMA and the non-emission area NEMA of the first and second sub-pixels SP1′, SP2′, and SP3′ may be defined by the light blocking patterns LBP. An area overlapping the light blocking patterns LBP in the third direction DR3 may correspond to the non-emission area NEMA. Areas not overlapping the light blocking patterns LBP in the third direction DR3 may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3 in the third direction DR3. For example, each of the light blocking patterns LBP may be formed as the first to third color filters CF1, CF2, and CF3 overlap with each other in the third direction DR3. In another embodiment, a light blocking pattern between the first and second color filters CF1 and CF2 among the light blocking patterns LBP may be formed as a multi-layer in which the first and second color filters CF1 and CF2 overlap with each other in the third direction DR3, and a light blocking pattern between the second and third color filters CF2 and CF3 among the light blocking patterns LBP may be formed as a multi-layer in which the second and third color filters CF2 and CF3 overlap with each other in the third direction DR3. A light blocking pattern between the first color filter CF1 and a third color filter CF3 of an adjacent pixel may be formed as a multi-layer in which the first and third color filters CF1 and CF3 overlap with each other in the third direction DR3. As such, each of the first to third color filters CF1, CF2, and CF3 may extend to the non-emission area NEMA to form the light blocking patterns LBP.

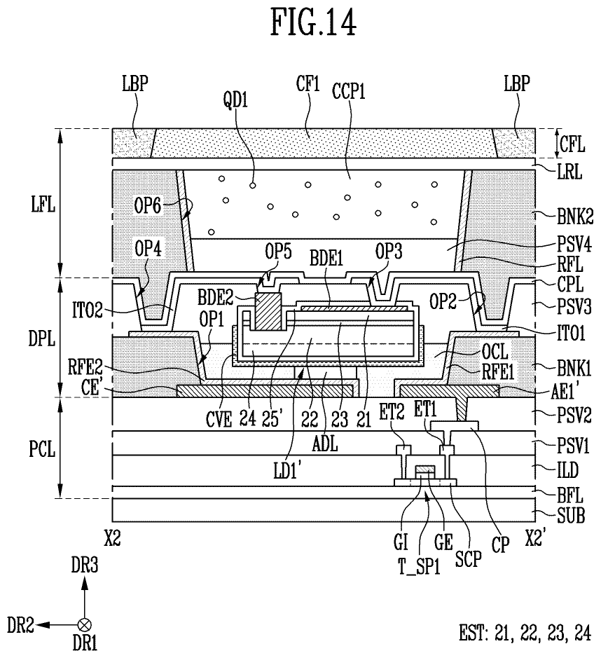

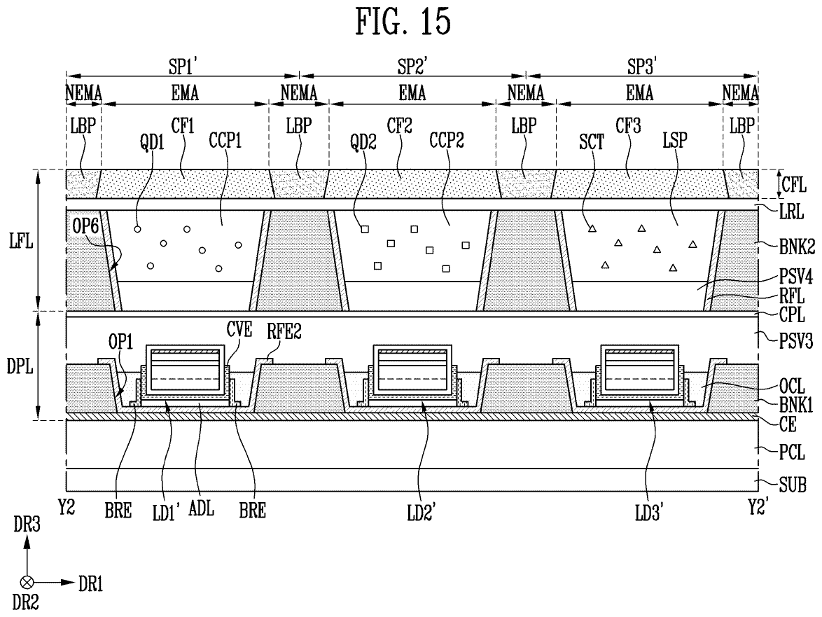

FIGS. 14 and 15 are schematic cross-sectional views illustrating a modified embodiment of the pixel in accordance with the second embodiment shown in FIG. 11. FIG. 14 is a schematic cross-sectional view taken along line X2-X2′ shown in FIG. 11, and FIG. 15 is a sectional view taken along line Y2-Y2′ shown in FIG. 11. Hereinafter, in FIGS. 14 and 15, descriptions of portions overlapping those which have been described with reference to FIGS. 12 and 13, will be omitted.

Referring to FIGS. 11, 14, and 15, a first light emitting element LD1′ may further include an insulating film 25′ covering at least a portion of an outer circumferential surface of a light emitting stack structure EST configured with a first semiconductor layer 21, a second semiconductor layer 22, an active layer 23, and an auxiliary layer 24. The insulating film 25′ may entirely cover the outer circumferential surface including a bottom surface of the light emitting stack structure EST (i.e., a bottom surface of the auxiliary layer 24 shown in FIG. 14 or a bottom surface of the second semiconductor layer 22 in case that the auxiliary layer 24 is omitted). For example, unlike the insulating film 25 which has been described with reference to FIG. 12, the insulating film 25′ may further cover the bottom surface of the light emitting stack structure EST.

Accordingly, the insulating film 15′ may be interposed between a cover electrode CVE covering the bottom surface of the light emitting stack structure EST and the light emitting stack structure EST. The cover electrode CVE may supplement a limited connection area of a second bonding electrode BDE2 and the second semiconductor layer 22. For example, an electric field may be formed not only in an area between the second bonding electrode BDE2 and a first bonding electrode BDE1 but also in an area between the cover electrode CVE and the first bonding electrode BDE1. Accordingly, a current density in the active layer 23 may be entirely maintained at a constant level, and thus the light emission area of the first light emitting element LD1′ may be relatively increased. For example, the light emission efficiency of the first light emitting element LD1′ may be improved.

In an embodiment, the cover electrode CVE may cover the entire bottom surface of the light emitting stack structure EST, which is covered by the insulating film 25′. The electric field may be effectively formed in the area between the sub-common electrode SCE and the first bonding electrode BDE1, and thus the light emission efficiency of the first light emitting element LD1′ may be further improved.

In an embodiment, a side surface of the active layer 23 and a side surface of the first semiconductor layer 21 may not be covered by the cover electrode CVE. The current density in the active layer 23 may be entirely maintained at a constant level, and thus the light emission efficiency of the first light emitting element LD1′ may be further improved.

In an embodiment, the cover electrode CVE may entirely cover a side surface of the auxiliary layer 24 and a side surface of the second semiconductor layer 22. The electric field may be more effectively formed in the area between the cover electrode CVE and the first bonding electrode BDE1, and thus the light emission efficiency of the first light emitting element LD1′ may be further improved. In accordance with embodiments, the insulating film 25′ may be interposed between the cover electrode CVE, and the side surface of the auxiliary layer 24 and the side surface of the second semiconductor layer 22.

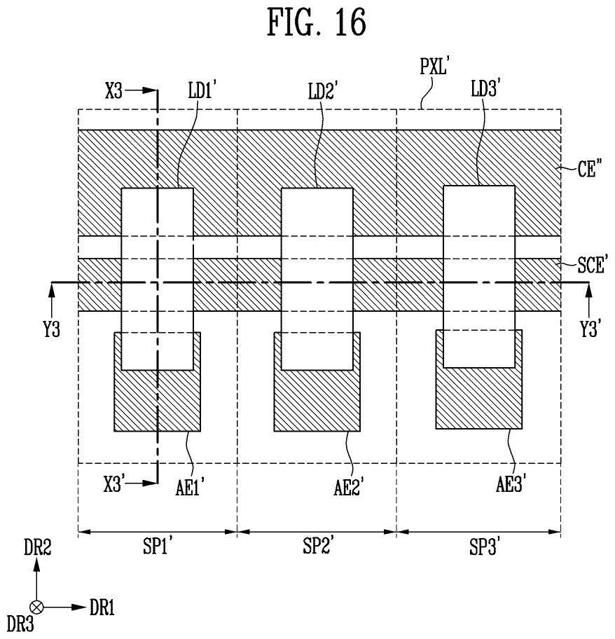

FIG. 16 is a plan view illustrating a third embodiment of the one pixel among the pixels included in the display panel shown in FIG. 3.

Referring to FIG. 16, a pixel PXL′ may include first to third sub-pixels SP1′, SP2′, and SP3′. The first to third sub-pixels SP1′, SP2′, and SP3′ may be arranged in the first direction DR1. However, the arrangement of the pixel PXL′ is not limited thereto, and may be variously changed. For example, the first to third sub-pixels SP1′, SP2′, and SP3′ may be arranged in zigzag.

First to third pixel electrodes AE1′, AE2′, and AE3′ may be disposed in the first to third sub-pixels SP1′, SP2′, and SP3′, respectively. The first pixel electrode AE1′ may be provided as a pixel electrode (AE shown in FIG. 2) of a sub-pixel circuit (SPC shown in FIG. 2) of the first sub-pixel SP1′. The second pixel electrode AE2′ may be provided as a pixel electrode (AE shown in FIG. 2) of a sub-pixel circuit (SPC shown in FIG. 2) of the second sub-pixel SP2′. The third pixel electrode AE3′ may be provided as a pixel electrode (AE shown in FIG. 2) of a sub-pixel circuit (SPC shown in FIG. 2) of the third sub-pixel SP3′.

A common electrode CE″ may be spaced apart from the first to third pixel electrodes AE1′, AE2′, and AE3′. The common electrode CE″ and the first to third pixel electrodes AE1′, AE2′, and AE3′ may be disposed at a same height. The common electrode CE″ may be spaced apart from the first to third pixel electrodes AE1′, AE2′, and AE3′ in the second direction DR2. In embodiments, the common electrode CE″ may extend in the first direction DR1 and may serve as a common electrode of the pixel PXL′ and other pixels adjacent to the pixel PXL′. Although not shown in the drawing, the common electrode CE″ may extend in the second direction DR2 in addition to the first direction DR1 and may serve as a common electrode of all the sub-pixels SP shown in FIG. 3. As such, the common electrode CE″ may have various shapes.

A sub-common electrode SCE′ may be spaced apart from the first to third pixel electrodes AE1′, AE2′, and AE3′ and the common electrode CE″. The sub-common electrode SCE′ and the first to third pixel electrodes AE1′, AE2′, and AE3′ and the common electrode CE″ may be disposed at a same height. The sub-common electrode SCE′ may be disposed between the first to third pixel electrodes AE1′, AE2′, and AE3′ and the common electrode CE″ in a plan view. In embodiments, the sub-common electrode SCE′ may extend in the first direction DR1 and may serve as a common electrode of the pixel PXL′ and other pixels adjacent to the pixel PXL′. Although not shown in the drawing, the sub-common electrode SCE′ may extend in the second direction DR2 in addition to the first direction DR1 and may serve as a common electrode of all the sub-pixels SP shown in FIG. 3. As such, the sub-common electrode SCE′ may have various shapes.

In accordance with embodiments, the sub-common electrode SCE′ may be electrically connected to the common electrode CE″. For example, a bridge electrode may be provided, which is disposed with the common electrode CE″ and the sub-common electrode SCE′ with at least one insulating layer interposed between the common electrode CE″ and the sub-common electrode SCE′. The bridge electrode may be electrically connected to each of the common electrode CE″ and the sub-common electrode SCE′ through a contact hole penetrating the at least one insulating layer. In accordance with embodiments, the sub-common electrode SCE′ may be electrically insulated from the common electrode CE″.

The common electrode CE″, the sub-common electrode SCE′, and the first to third pixel electrodes AE1′, AE2, and AE3′ may define an electrode layer. The common electrode CE″, the sub-common electrode SCE′, and the first to third pixel electrodes AE1′, AE2, and AE3′ may be implemented as patterns of the electrode layer.

First to third light emitting elements LD1′, LD2′, and LD3′ may be disposed on the first to third pixel electrodes AE1′, AE2′, and AE3′, the sub-common electrode SCE′, and the common electrode CE″. The first light emitting element LD1′ may be electrically connected to the first pixel electrode AE1′, the sub-common electrode SCE′, and the common electrode CE″. The first light emitting element LD1′ may be provided as a light emitting element (LD shown in FIG. 2) connected to the sub-pixel circuit (SPC shown in FIG. 2) of the first sub-pixel SP1′. The second light emitting element LD2′ may be electrically connected to the second pixel electrode AE2′, the sub-common electrode SCE′, and the common electrode CE″. The second light emitting element LD2′ may be provided as a light emitting element (LD shown in FIG. 2) connected to the sub-pixel circuit (SPC shown in FIG. 2) of the second sub-pixel SP2′. The third light emitting element LD3′ may be electrically connected to the third pixel electrode AE3′, the sub-common electrode SCE′, and the common electrode CE″. The third light emitting element LD3′ may be provided as a light emitting element (LD shown in FIG. 2) connected to the sub-pixel circuit (SPC shown in FIG. 2) of the third sub-pixel SP3′.

The first light emitting element LD1′, the second light emitting element LD2′, and the third light emitting element LD3′ may be inorganic light emitting diodes including an inorganic light emitting material. However, embodiments are not limited thereto. In another embodiment, the first light emitting element LD1′, the second light emitting element LD2′, and the third light emitting element LD3′ may be organic light emitting diodes including an organic light emitting material.

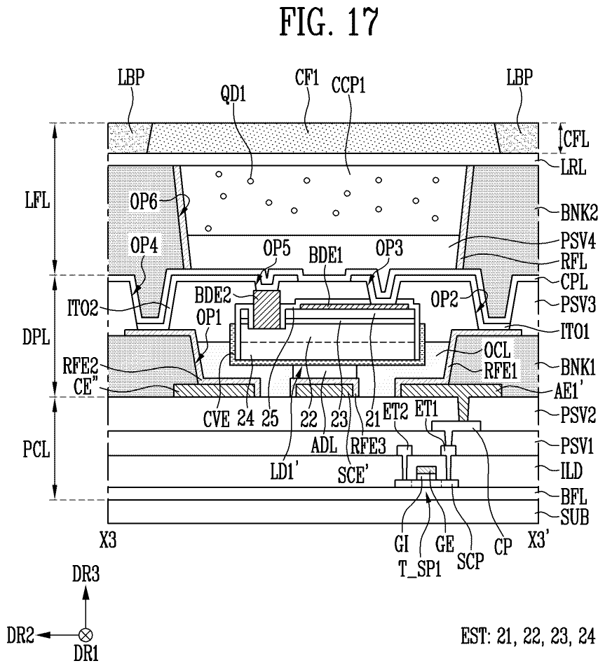

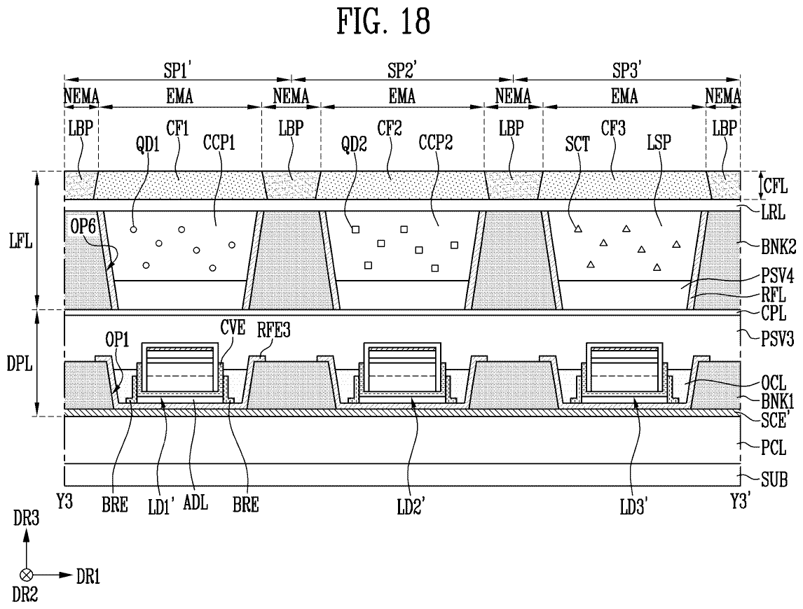

FIGS. 17 and 18 are schematic cross-sectional views illustrating the pixel in accordance with the third embodiment shown in FIG. 16. FIG. 17 is a schematic cross-sectional view taken along line X3-X3′ shown in FIG. 16, and FIG. 13 is a schematic cross-sectional view taken along line Y3-Y3′ shown in FIG. 16.

Referring to FIGS. 16 and 17, a pixel circuit layer PCL, a display element layer DPL, and a light functional layer LFL may be sequentially disposed on a substrate SUB.

The pixel circuit layer PCL may be substantially identical to the pixel circuit layer PCL which has been described with reference to FIGS. 7 and 8. Therefore, descriptions of overlapping portions will be omitted.

The display element layer DPL may be disposed on a second passivation layer PSV2. The display element layer DPL may include a first pixel electrode AE1′, a common electrode CE″, a sub-common electrode SCE′, a first bank BNK1, first to third reflective electrodes RFE1, RFE2, and RFE3, an adhesive layer ADL, an overcoat layer OCL, a first light emitting element LD1′, a third passivation layer PSV3, first and second transparent electrodes ITO1 and ITO2, and a capping layer CPL.

An electrode layer including the first pixel electrode AE1′, the common electrode CE″, and the sub-common electrode SCE′ may be disposed on the pixel circuit layer PCL.

The first pixel electrode AE1′ may be electrically connected to a connection electrode CP through a contact hole penetrating the second passivation layer PSV2. As such, the first pixel electrode AE1′ may be electrically connected to a transistor T_SP1.

The common electrode CE″ may be spaced apart from the first pixel electrode AE1′ in the second direction DR2. The common electrode CE″ may be electrically connected to the second power voltage node VSSN shown in FIG. 2. Accordingly, the second power voltage applied to the second power voltage node VSSN may be transferred to the common electrode CE″.

The sub-common electrode SCE′ may be disposed between the first pixel electrode AE1′ and the common electrode CE″ while being spaced apart from the first pixel electrode AE1′ and the common electrode CE″.

The first bank BNK1 may be disposed on the first pixel electrode AE1′, the common electrode CE″, and the sub-common electrode SCE′. The first bank BNK1 may have a first opening OP1 exposing portions of the first pixel electrode AE1′, the common electrode CE″, and the sub-common electrode SCE′. The first light emitting element LD1′ may be disposed in the first opening OP1 of the first bank BNK1. As such, the first bank BNK1 may be provided as a pixel defining layer defining an area in which the first light emitting element LD1′ is located.

The first bank BNK1 may include a light blocking material, and may prevent light mixture between adjacent sub-pixels. In embodiments, the first bank BNK1 may include an organic material. For example, the first bank BNK1 may include an organic insulating material such as an acrylic resin, an epoxy resin, a phenolic resin, a polyamide resin, or a polyimide resin.

The first reflective electrode RFE1 may be disposed on the exposed portion of the first pixel electrode AE1′ and a side surface of the first bank BNK1 adjacent to the exposed portion of the first pixel electrode AE1′. The second reflective electrode RFE2 may be disposed on the exposed portion of the common electrode CE″ and a side surface of the first bank BNK1 adjacent to the exposed portion of the common electrode CE″. The third reflective electrode RFE3 may be disposed on the exposed portion of the sub-common electrode SCE′ and a side surface (see FIG. 18) of the first bank BNK1 adjacent to the exposed portion of the sub-common electrode SCE′. The first to third reflective electrodes RFE1, RFE2, and RFE3 may include a conductive material suitable for reflecting light. Accordingly, the light emission efficiency of the first light emitting element LD1′ may be improved. In embodiments, the first to third reflective electrodes RFE1, RFE2, and RFE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy thereof. However, embodiments are not limited thereto.

The adhesive layer ADL may be disposed on the sub-common electrode SCE′ in the first opening OP1 of the first bank BNK1. In accordance with embodiments, the third reflective electrode RFE3 may be interposed between the sub-common electrode SCE′ and the adhesive layer ADL. The adhesive layer ADL may include an insulating material having adhesive properties. For example, the adhesive layer ADL may include an organic insulating material having adhesion. The adhesive layer ADL may have a constant height in the third direction DR3. Accordingly, the first light emitting element LD1′ adhered on the adhesive layer ADL may be spaced apart from components disposed under the adhesive layer ADL. For example, the first light emitting element LD1′ may be spaced apart from the first and second reflective electrodes RFE1 and RFE2 disposed under the adhesive layer ADL. Accordingly, the adhesive layer ADL may prevent an electrical short circuit which may occur in case that a cover electrode CVE included in the first light emitting element LD1′ and the first and second reflective electrodes RFE1 and RFE2 are in contact with each other. Also, the adhesive layer ADL may fix the first light emitting element LD1′ attached to the adhesive layer ADL.

On the first to third reflective electrodes RFE1, RFE2, and RFE3 and the second passivation layer PSV2, the overcoat layer OCL may be disposed in the first opening OP1 of the first bank BNK1. The first light emitting element LD1′ attached on the adhesive layer ADL may be disposed on the overcoat layer OCL. The first light emitting element LD1′ may be partially buried in the overcoat layer OCL.

The overcoat layer OCL along with the above-described adhesive layer ADL may fix the first light emitting element LD1′ not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The first light emitting element LD1′ is the same as described with reference to FIG. 12. Therefore, overlapping descriptions will be omitted.

The third passivation layer PSV3 may be disposed over the first and second reflective electrodes RFE1 and RFE2, the first light emitting element LD1′, and the overcoat layer OCL. The third passivation layer PSV3 may protect components disposed under the third passivation layer PSV3, and provide a flat surface. The third passivation layer PSV3 and one of a first passivation layer PSV1 and the second passivation layer PSV2 may include a same material, but embodiments are not limited thereto.

The third passivation layer PSV3 may have second to fifth openings OP2, OP3, OP4, and OP5. The second opening OP2 may expose a portion of the first reflective electrode RFE1 in a plan view. The third opening OP3 may expose a top surface of a first bonding electrode BDE1 in a plan view. The fourth opening OP4 may expose a portion of the second reflective electrode RFE2 in a plan view. The fifth opening OP5 may expose a top surface of a second bonding electrode BDE2 in a plan view.

The first and second transparent electrodes ITO1 and ITO2 may be disposed on the third passivation layer PSV3. The first transparent electrode ITO1 may electrically connect the first reflective electrode RFE1 exposed by the second opening OP2 to the first bonding electrode BDE1 exposed by the third opening OP3. The second transparent electrode ITO2 may electrically connect the second reflective electrode RFE2 exposed by the fourth opening OP4 to the second bonding electrode BDE2 exposed by the fifth opening OP5. Accordingly, the first bonding electrode BDE1 may be electrically connected to the first pixel electrode AE1′ through the first transparent electrode ITO1 and the first reflective electrode RFE1. The second bonding electrode BDE2 may be electrically connected to the common electrode CE″ through the second transparent electrode ITO2 and the second reflective electrode RFE2.

In embodiments, the first and second transparent electrodes ITO1 and ITO2 may be formed substantially transparent or translucent to satisfy a light transmittance. In embodiments, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

The capping layer CPL may be disposed on the third passivation layer PSV3. The capping layer CPL may protect components disposed under the capping layer CPL, such as the first and second transparent electrodes ITO1 and ITO2 and the first light emitting element LD1′, from external moisture, humidity, and the like. The capping layer CPL may include at least one of silicon nitride, silicon oxide, silicon oxynitride, and a metal oxide such as aluminum oxide. However, the material of the capping layer CPL is not limited thereto.

In the pixel in accordance with the third embodiment of the disclosure, the first light emitting element LD1′ may further include the cover electrode CVE covering a bottom surface of a light emitting stack structure EST (i.e., a bottom surface of an auxiliary layer 24 shown in FIG. 17 or a bottom surface of a second semiconductor layer 22 in case that the auxiliary layer 24 is omitted) and at least a portion of a side surface adjacent to the bottom surface of the light emitting stack structure EST. In accordance with embodiments, an insulating film 25 may be interposed between the cover electrode CVE and the portion of the side surface of the light emitting stack structure EST. The cover electrode CVE and one of the first and second transparent electrodes ITO1 and ITO2, the first to third reflective electrodes RFE1, RFE2, and RFE3, the first pixel electrode AE1′, the sub-common electrode SCE′, and the common electrode CE″ may include a same material, but embodiments are not limited thereto.

The cover electrode CVE may be electrically connected to the common electrode CE′ through a bridge electrode (BRE shown in FIG. 18) which will be described below with reference to FIG. 18. Therefore, a voltage applied to the sub-common electrode SCE′ may be applied to the cover electrode CVE. The cover electrode CVE may supplement a limited connection area of the second bonding electrode BDE2 and the second semiconductor layer 22. In case that the first light emitting element LD1′ is a lateral chip type light emitting element as shown in FIG. 17, it may be difficult to sufficiently secure the connection area of the second bonding electrode BDE2 electrically connected to the common electrode CE″ and the second semiconductor layer 22. In case that that the cover electrode CVE does not exist, a current density in an active layer 23 may be concentrated on a specific area (e.g., an area adjacent to the second bonding electrode BDE2 in an area between the first bonding electrode BDE1 and the second bonding electrode BDE2), and accordingly, the light emission efficiency in an area except the specific area may be relatively low. In the disclosure, the cover electrode CVE covering the bottom surface of the light emitting stack structure EST and the portion of the side surface adjacent to the bottom surface of the light emitting structure EST may perform a function substantially identical (or similar) to a function of the second bonding electrode BDE2 connected to the second semiconductor layer 22. For example, an electric field may be formed in an area between the cover electrode CVE and the first bonding electrode BDE1 in addition to the area between the second bonding electrode BDE2 and the first bonding area BDE1. Accordingly, the current density in the active layer 23 may be entirely maintained at a constant level, and thus the light emission area of the first light emitting element LD1′ may become relatively large. For example, the light emission efficiency of the first light emitting element LD1′ may be improved.

In an embodiment, the cover electrode CVE may cover (e.g., directly cover) the entire bottom surface of the light emitting stack structure EST, which is not covered by the insulating film 25. For example, the entire bottom surface of the light emitting stack structure EST may be in direct contact with the cover electrode CVE. The electric field may be effectively formed in the area between the cover electrode CVE and the first bonding electrode BDE1, and thus the light emission efficiency of the first light emitting element LD1′ may be further improved.

In an embodiment, a side surface of the active layer 23 and a side surface of the first semiconductor layer 21 may not be covered by the cover electrode CVE. The current density in the active layer 23 may be entirely maintained at a constant level, and thus the light emission efficiency of the first light emitting element LD1′ may be further improved.

In an embodiment, the cover electrode CVE may entirely cover a side surface of the auxiliary layer 24 and a side surface of the second semiconductor layer 22. The electric field may be further formed in the area between the cover electrode CVE and the first bonding electrode BDE1, and thus the light emission efficiency of the first light emitting element LD1′ may be further improved. In accordance with embodiments, the insulating film 25 may be interposed between the cover electrode CVE, and the side surface of the auxiliary layer 24 and the side surface of the second semiconductor layer 22.

In an embodiment, a voltage having a level substantially equal to a level of a voltage applied to the common electrode CE″ may be applied to the sub-common electrode SCE′. Accordingly, the voltage having the level substantially equal to the level of the voltage applied to the common electrode CE″ may be applied to the cover electrode CVE electrically connected to the sub-common electrode SCE′. In accordance with embodiments, in a partial area of the display area (DA shown in FIG. 3) and/or a partial area of the non-display area (NDA shown in FIG. 3), the sub-common electrode SCE′ may be electrically connected to (or in contact with) the common electrode CE″ and/or a power line connected to the second power voltage node (VSSN shown in FIG. 2).

In an embodiment, a voltage having a level different from the level of the voltage applied to the common electrode CE″ may be applied to the sub-common electrode SCE′. Accordingly, the voltage having the level different from the level of the voltage applied to the common electrode CE″ may be applied to the cover electrode CVE electrically connected to the sub-common electrode SCE′. For example, a voltage having a level between the level of the voltage applied to the common electrode CE″ and a level of a voltage applied to the first pixel electrode AE1′ may be applied to the sub-common electrode SCE′. For example, the voltage generator (140 shown in FIG. 1) may generate a third power voltage having a level between the first power voltage and the second power voltage in addition to the first power voltage and the second power voltage. The generated third power voltage may be provided to the sub-common electrode SCE′ through a partial voltage line among the power lines PL. However, embodiments are not limited thereto, and the level of the voltage applied to the sub-common electrode SCE′ may be variously changed within a range in which the above-described electric field can be effectively formed.

In case that the cover electrode CVE is in direct contact with the light emitting stack structure EST (e.g., in case that the cover electrode CVE is in direct contact with the bottom surface of the auxiliary layer 24 as shown in FIG. 17), the voltage having the level substantially equal to the level of the voltage applied to the common electrode CE″ may be applied to the sub-common electrode SCE′. As compared with an embodiment that the voltage having the level different from the level of the voltage applied to the common electrode CE″ is applied to the sub-common electrode SCE′, the electric field may be more effectively formed in the area between the cover electrode CVE and the first bonding electrode BDE1.

In the above, the pixel circuit layer PCL and the display element layer DPL of the first sub-pixel SP1′ have been described. Each of the second and third sub-pixels SP2′ and SP3′ shown in FIG. 16 may be configured identically to the first sub-pixel SP1′ within a range in which it is not differently described herein.

The light functional layer LFL may be substantially identical to the light functional layer LFL which has been described with reference to FIG. 12. Therefore, descriptions of overlapping portions will be omitted.

Referring to FIGS. 16 and 18, the pixel circuit layer PCL and the display element layer DPL may be the same as described with reference to FIG. 17. In the pixel circuit layer PCL, sub-pixel circuits respectively corresponding to the first to third sub-pixels SP1′, SP2′, and SP3′ may be provided. In the display element layer DPL, first to third light emitting elements LD1′, LD2′, and LD3′ respectively corresponding to the first to third sub-pixels SP1′, SP2′, and SP3′ may be provided. The first to third light emitting elements LD1′, LD2′, and LD3′ may overlap first openings OP1 of the first bank BNK1 in the third direction DR3. The first light emitting element LD1′ may be connected between the common electrode CE″ and the transistor (T_SP1 shown in FIG. 17) included in a sub-pixel circuit of the first sub-pixel SP1′. The second light emitting element LD2′ may be connected between the common electrode CE″ and a transistor included in a sub-pixel circuit of the second sub-pixel SP2′. The third light emitting element LD3′ may be connected between the common electrode CE″ and a transistor included in a sub-pixel circuit of the third sub-pixel SP3′. The first to third light emitting elements LD1′, LD2, and LD3′ may be connected to the sub-common electrode SCE′.

As shown in FIG. 18, the cover electrode CVE may be electrically connected to the sub-common electrode SCE′ through a bridge electrode BRE. For example, the bridge electrode BRE may be electrically in contact with the third reflective electrode RFE3 electrically in contact with the sub-common electrode SCE′ while being electrically in contact with the cover electrode CVE covering the side surface of the light emitting stack structure EST. In embodiments, the bridge electrode BRE may extend along a side surface of the adhesive layer ADL attached to the cover electrode CVE under the cover electrode CVE. For example, in a structure in a cross-sectional view shown in FIG. 18, a width of the adhesive layer ADL in the first direction DR1 may be substantially equal to or greater than a width of the cover electrode CVE in the first direction DR1, and the bridge electrode BDE may cover (e.g., directly cover) the side surface of the adhesive layer ADL. The adhesive layer ADL may improve the reliability of the bridge electrode BDE. For example, in case that the adhesive layer ADL does not exist, the bridge electrode BRE may not be sufficiently supported in a separation area between the cover electrode CVE and the third reflective electrode RFE3, and accordingly, a problem may occur, in that the bridge electrode BRE may be disconnected. Hereinafter, in relation to the pixel circuit layer PCL and the display element layer DPL, descriptions of portion overlapping those described with reference to FIG. 17 will be omitted.

The light functional layer LFL may be provided on the display element layer DPL. The light functional layer LFL may be the same as described with reference to FIG. 17. Therefore, descriptions of overlapping portions will be omitted.

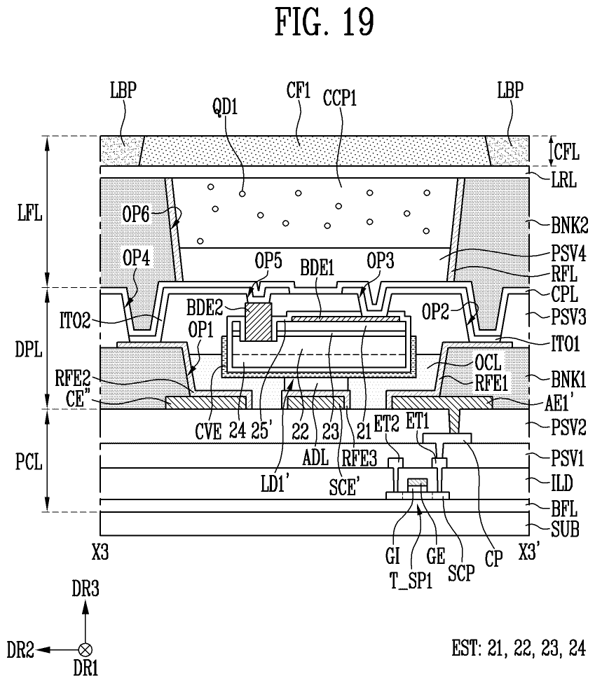

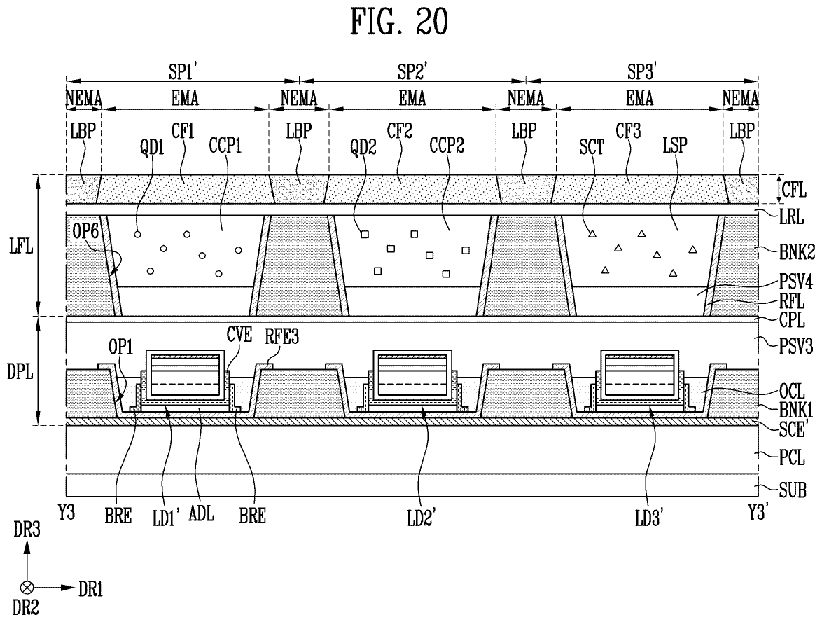

FIGS. 19 and 20 are schematic cross-sectional views illustrating a modified embodiment of the pixel in accordance with the third embodiment shown in FIG. 16. FIG. 19 is a schematic cross-sectional view taken along line X3-X3′ shown in FIG. 16, and FIG. 20 is a schematic cross-sectional view taken along line Y3-Y3′ shown in FIG. 16. Hereinafter, in FIGS. 19 and 20, descriptions of portions overlapping those which have been described with reference to FIGS. 17 and 18, will be omitted.

Referring to FIGS. 16, 19, and 20, a first light emitting element LD1′ may further include an insulating film 25′ covering at least a portion of an outer circumferential surface of a light emitting stack structure EST configured with a first semiconductor layer 21, a second semiconductor layer 22, an active layer 23, and an auxiliary layer 24. The insulating film 25′ may entirely cover the outer circumferential surface including a bottom surface of the light emitting stack structure EST (i.e., a bottom surface of the auxiliary layer 24 shown in FIG. 19 or a bottom surface of the second semiconductor layer 22 in case that the auxiliary layer 24 is omitted). For example, unlike the insulating film 25 which has been described with reference to FIG. 17, the insulating film 25′ may further cover the bottom surface of the light emitting stack structure EST.

Accordingly, the insulating film 15′ may be interposed between a cover electrode CVE covering the bottom surface of the light emitting stack structure EST and the light emitting stack structure EST. The cover electrode CVE may supplement a limited connection area of a second bonding electrode BDE2 and the second semiconductor layer 22. For example, an electric field may be formed not only in an area between the second bonding electrode BDE2 and a first bonding electrode BDE1 but also in an area between the cover electrode CVE and the first bonding electrode BDE1. Accordingly, a current density in the active layer 23 may be entirely maintained at a constant level, and thus the light emission area of the first light emitting element LD1′ may be relatively increased. For example, the light emission efficiency of the first light emitting element LD1′ may be improved.

In an embodiment, the cover electrode CVE may cover the entire bottom surface of the light emitting stack structure EST, which is covered by the insulating film 25′. The electric field may be effectively formed in the area between a sub-common electrode SCE′ and the first bonding electrode BDE1, and thus the light emission efficiency of the first light emitting element LD1′ may be further improved.

In an embodiment, a side surface of the active layer 23 and a side surface of the first semiconductor layer 21 may not be covered by the cover electrode CVE. The current density in the active layer 23 may be entirely maintained at a constant level, and thus the light emission efficiency of the first light emitting element LD1′ may be further improved.

In an embodiment, the cover electrode CVE may entirely cover a side surface of the auxiliary layer 24 and a side surface of the second semiconductor layer 22. The electric field may be more effectively formed in the area between the cover electrode CVE and the first bonding electrode BDE1, and thus the light emission efficiency of the first light emitting element LD1′ may be further improved. In accordance with embodiments, the insulating film 25′ may be interposed between the cover electrode CVE, and the side surface of the auxiliary layer 24 and the side surface of the second semiconductor layer 22.

In an embodiment, a voltage having a level substantially equal to a level of a voltage applied to a common electrode CE″ may be applied to the sub-common electrode SCE′. Accordingly, the voltage having the level substantially equal to the level of the voltage applied to the common electrode CE″ may be applied to the cover electrode CVE electrically connected to the sub-common electrode SCE′. In accordance with embodiments, in a partial area of the display area (DA shown in FIG. 3) and/or a partial area of the non-display area (NDA shown in FIG. 3), the sub-common electrode SCE′ may be electrically connected to (or in contact with) the common electrode CE″ and/or a power line connected to the second power voltage node (VSSN shown in FIG. 2).

In an embodiment, a voltage having a level different from the level of the voltage applied to the common electrode CE″ may be applied to the sub-common electrode SCE′. Accordingly, the voltage having the level different from the level of the voltage applied to the common electrode CE″ may be applied to the cover electrode CVE electrically connected to the sub-common electrode SCE′. For example, a voltage having a level between the level of the voltage applied to the common electrode CE″ and a level of a voltage applied to a first pixel electrode AE1′ may be applied to the sub-common electrode SCE′. For example, the voltage generator (140 shown in FIG. 1) may generate a third power voltage having a level between the first power voltage and the second power voltage in addition to the first power voltage and the second power voltage. The generated third power voltage may be provided to the sub-common electrode SCE′ through a partial voltage line among the power lines PL. However, embodiments are not limited thereto, and the level of the voltage applied to the sub-common electrode SCE′ may be variously changed within a range in which the above-described electric field can be effectively formed.

In case that the insulating film 25′ is interposed between the cover electrode CVE and a bottom surface of the light emitting stack structure EST (i.e., in case that the cover electrode CVE is not in direct contact with a top surface of the light emitting stack structure EST as shown in FIG. 19), the voltage having the level different from the level of the voltage applied to the common electrode CE″ may be applied to the sub-common electrode SCE′. As compared with an embodiment that the voltage having the level substantially equal to the level of the voltage applied to the common electrode CE″ is applied to the sub-common electrode SCE′, the electric field may be more effectively formed in the area between the cover electrode CVE and the first bonding electrode BDE1.

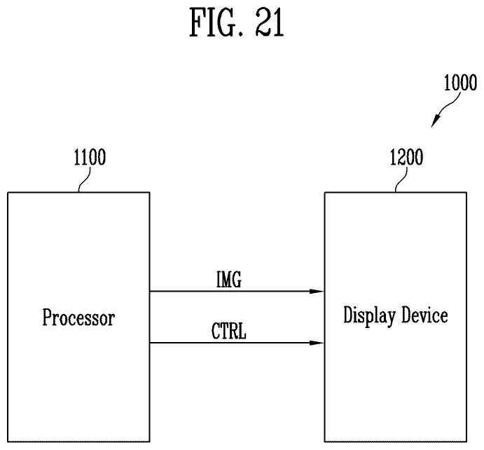

FIG. 21 is a schematic block diagram illustrating a display system in accordance with an embodiment of the disclosure.

Referring to FIG. 21, a display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured identical to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

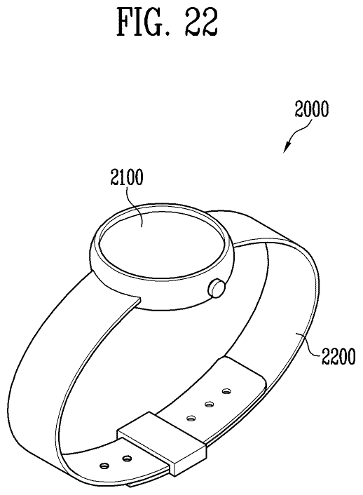

FIGS. 22 to 25 are perspective views illustrating applications of the display system shown in FIG. 21.

Referring to FIG. 22, the display system 1000 shown in FIG. 21 may be applied to a smart watch 2000 including a display part 2100 and a strap part 2200.

The smart watch 2000 may be a wearable electronic device. For example, the smart watch 2000 may have a structure in which the strap part 2200 may be mounted on a wrist of a user. The display system 1000 and/or the display device 1200 may be applied to the display part 2100, so that image data including time information may be provided to the user.

Referring to FIG. 23, the display system 1000 shown in FIG. 21 may be applied to an automotive display system 3000. The automotive display system 3000 may include a computing system provided at the inside or outside of a vehicle to provide image data.

For example, the display system 1000 and/or the display device 1200 may be applied to at least one of an infortainment panel 3100, a cluster 3200, a passenger seat display 3300, a head-up display 3400, a side mirror display 3500, and a read seat display 3600, which are provided in the vehicle.

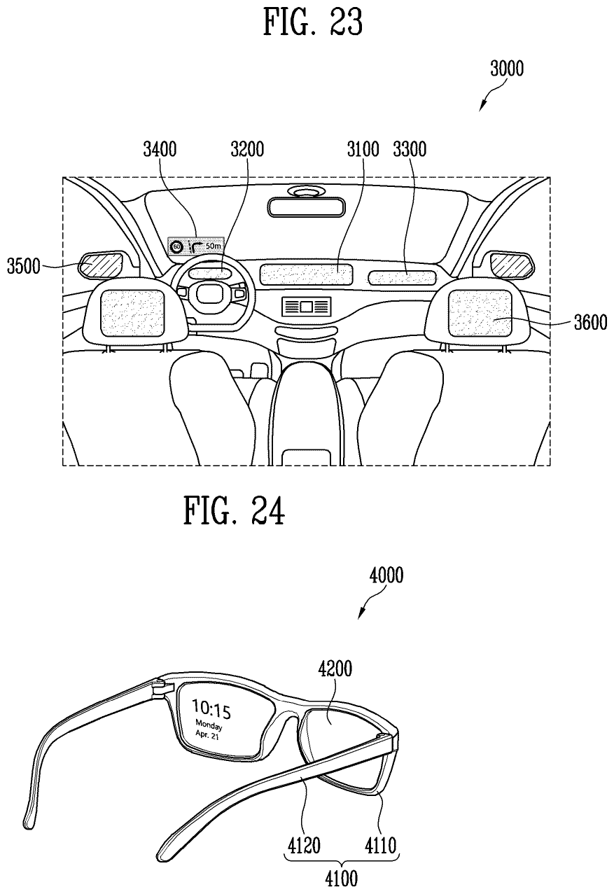

Referring to FIG. 24, the display system 1000 shown in FIG. 21 may be applied to smart glasses 4000. The smart glasses 4000 may be a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, a transparent synthetic resin, or the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

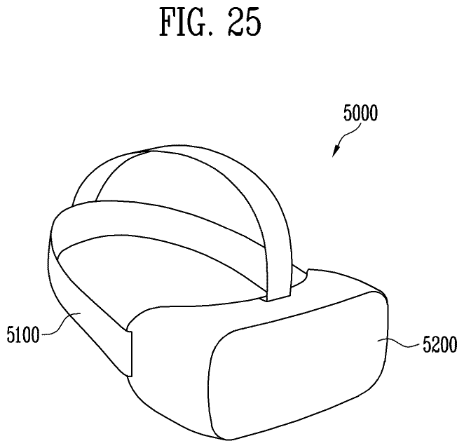

Referring to FIG. 25, the display system 1000 shown in FIG. 21 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

In accordance with the disclosure, the display device may include a light emitting stack structure including a first semiconductor layer, a second semiconductor layer disposed on the first semiconductor layer, and an active layer interposed between the first semiconductor layer and the second semiconductor layer, a first bonding electrode which is connected to the first semiconductor layer and is electrically connected to a pixel electrode, a second bonding electrode which is connected to the second semiconductor layer and is electrically connected to a common electrode, and a sub-common electrode covering at least a top surface of the light emitting stack structure. The display device may be a display device including a flip chip type light emitting element. The sub-common electrode may perform a function substantially identical (or similar) to a function of the second bonding electrode electrically connected to the common electrode. Accordingly, an electric field can be formed not only between the first bonding electrode and the second bonding electrode but also between the first bonding electrode and the sub-common electrode, and thus the light emission efficiency of the display device can be improved.

In accordance with the disclosure, the display device may include a light emitting stack structure including a first semiconductor layer, a second semiconductor layer disposed on the first semiconductor layer, and an active layer interposed between the first semiconductor layer and the second semiconductor layer, a first bonding electrode which is connected to the first semiconductor layer and is electrically connected to a pixel electrode, a second bonding electrode which is connected to the second semiconductor layer and is electrically connected to a common electrode, and a cover electrode covering a bottom surface of the light emitting stack structure and a portion of a side surface adjacent to the bottom surface of the light emitting stack structure. The display device may be a display device including a lateral chip type light emitting element. The cover electrode may perform a function substantially identical (or similar) to a function of the second bonding electrode electrically connected to the common electrode. Accordingly, an electric field can be formed not only between the first bonding electrode and the second bonding electrode but also between the first bonding electrode and the cover electrode, and thus the light emission efficiency of the display device can be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel circuit layer including a sub-pixel circuit having at least one transistor;
an electrode layer disposed on the pixel circuit layer and including a pixel electrode electrically connected to the sub-pixel circuit and a common electrode spaced apart from the pixel electrode;
a light emitting stack structure disposed on the electrode layer and including a first semiconductor layer, a second semiconductor layer disposed on the first semiconductor layer, and an active layer interposed between the first semiconductor layer and the second semiconductor layer;
a first bonding electrode connected to the first semiconductor layer and electrically connected to the pixel electrode;
a second bonding electrode connected to a portion of the second semiconductor layer not overlapping the first semiconductor layer and the active layer in a plan view and electrically connected to the common electrode; and
a sub-common electrode covering at least a top surface of the light emitting stack structure.

2. The display device of claim 1, wherein the sub-common electrode further covers a portion of a side surface of the light emitting stack structure, which is adjacent to the top surface of the light emitting stack structure.

3. The display device of claim 2, wherein a side surface of the active layer and a side surface of the first semiconductor layer are not covered by the sub-common electrode.

4. The display device of claim 2, further comprising:
an insulating film covering at least a portion of an outer circumferential surface of the light emitting stack structure,
wherein the insulating film is interposed between the sub-common electrode and the portion of the side surface of the light emitting stack structure.

5. The display device of claim 4, wherein the insulating film is further interposed between the sub-common electrode and the top surface of the light emitting stack structure.

6. The display device of claim 1, wherein a level of a voltage applied to the sub-common electrode and a level of a voltage applied to the common electrode are equal.

7. The display device of claim 1, wherein a level of a voltage applied to the sub-common electrode and a level of a voltage applied to the common electrode are different.

8. The display device of claim 7, wherein the level of the voltage applied to the sub-common electrode is between the level of the voltage applied to the common electrode and a level of a voltage applied to the pixel electrode.

9. A display device comprising:
a pixel circuit layer including a sub-pixel circuit having at least one transistor;
an electrode layer disposed on the pixel circuit layer and including a pixel electrode electrically connected to the sub-pixel circuit and a common electrode spaced apart from the pixel electrode;
an adhesive layer disposed on the common electrode;
a light emitting stack structure disposed on the adhesive layer and including a first semiconductor, a second semiconductor layer disposed under the first semiconductor layer, and an active layer interposed between the first semiconductor layer and the second semiconductor layer;
a first bonding electrode connected to the first semiconductor layer and electrically connected to the pixel electrode;
a second bonding electrode connected to a portion of the second semiconductor layer not overlapping the first semiconductor layer and the active layer in a plan view and electrically connected to the common electrode;
a cover electrode covering a bottom surface of the light emitting stack structure and a portion of a side surface adjacent to the bottom surface of the light emitting stack structure; and
a bridge electrode electrically connected to each of the cover electrode and the common electrode.

10. The display device of claim 9, wherein a side surface of the active layer and a side surface of the first semiconductor layer are not covered by the cover electrode.

11. The display device of claim 9, further comprising:
an insulating film covering at least a portion of an outer circumferential surface of the light emitting stack structure,
wherein the insulating film is interposed between the cover electrode and the portion of the side surface of the light emitting stack structure.

12. The display device of claim 11, wherein the insulating film is further interposed between the cover electrode and the bottom surface of the light emitting stack structure.

13. A display device comprising:
a pixel circuit layer including a sub-pixel circuit having at least one transistor;
an electrode layer disposed on the pixel circuit layer and including a pixel electrode electrically connected to the sub-pixel circuit, a common electrode spaced apart from the pixel electrode, and a sub-common electrode spaced apart from each of the pixel electrode and the common electrode;
an adhesive layer disposed on the sub-common electrode;
a light emitting stack structure disposed on the adhesive layer and including a first semiconductor, a second semiconductor layer disposed under the first semiconductor layer, and an active layer interposed between the first semiconductor layer and the second semiconductor layer;
a first bonding electrode connected to the first semiconductor layer and electrically connected to the pixel electrode;
a second bonding electrode connected to a portion of the second semiconductor layer not overlapping the first semiconductor layer and the active layer in a plan view and electrically connected to the common electrode;
a cover electrode covering a bottom surface of the light emitting stack structure and a portion of a side surface adjacent to the bottom surface of the light emitting stack structure; and
a bridge electrode electrically connected to each of the cover electrode and the common electrode.

14. The display device of claim 13, wherein a side surface of the active layer and a side surface of the first semiconductor layer are not covered by the cover electrode.

15. The display device of claim 13, further comprising:
an insulating film covering at least a portion of an outer circumferential surface of the light emitting stack structure,
wherein the insulating film is interposed between the cover electrode and the portion of the side surface of the light emitting stack structure.

16. The display device of claim 15, wherein the insulating film is further interposed between the cover electrode and the bottom surface of the light emitting stack structure.

17. The display device of claim 13, wherein a level of a voltage applied to the sub-common electrode and a level of a voltage applied to the common electrode are equal.

18. The display device of claim 13, wherein a level of a voltage applied to the sub-common electrode and a level of a voltage applied to the common electrode are different.

19. The display device of claim 18, wherein the level of the voltage applied to the sub-common electrode is between the level of the voltage applied to the common electrode and a level of a voltage applied to the pixel electrode.

20. An electronic device comprising:
a processor to provide input image data; and
a display device to display an image based on the input image data,
wherein the display device comprises:
a pixel circuit layer including a sub-pixel circuit having at least one transistor;
an electrode layer disposed on the pixel circuit layer and including a pixel electrode electrically connected to the sub-pixel circuit and a common electrode spaced apart from the pixel electrode;
a light emitting stack structure disposed on the electrode layer and including a first semiconductor layer, a second semiconductor layer disposed on the first semiconductor layer, and an active layer interposed between the first semiconductor layer and the second semiconductor layer;
a first bonding electrode connected to the first semiconductor layer and electrically connected to the pixel electrode;
a second bonding electrode connected to a portion of the second semiconductor layer not overlapping the first semiconductor layer and the active layer in a plan view and electrically connected to the common electrode; and
a sub-common electrode covering at least a top surface of the light emitting stack structure.
